(19) United States
(12) Patent Application Publication
(10) Pub. No.: US 2025/0062589 A1
(43) Pub. Date: Feb. 20, 2025

(54) TITANIUM:SAPPHIRE (TI:SA) WAFERS, INTEGRATED TI:SA LASERS, AND METHODS OF FORMING THE SAME

(71) Applicant: YALE UNIVERSITY, New Haven, CT (US)

(72) Inventors: Hong Tang, New Haven, CT (US); Yubo Wang, New Haven, CT (US); Yu Guo, New Haven, CT (US); Jorge Holguin-Lerma, New Haven, CT (US)

(21) Appl. No.: 18/806,608

(22) Filed: Aug. 15, 2024

Related U.S. Application Data
(60) Provisional application No. 63/519,991, filed on Aug. 16, 2023.

(51) Int. Cl. H01S 3/16; G02B 6/42; H01S 3/08; H01S 3/0941

(52) U.S. Cl. CPC H01S 3/1636; G02B 6/4202; H01S 3/08059; H01S 3/09415; H01S 3/1625

(57) ABSTRACT

Provided herein are a method of preparing a Titanium:Sapphire (Ti:Sa) wafer and a photonic circuit integrated (PIC) Titanium:Sapphire (Ti:Sa) laser. The method includes depositing a titanium layer on a top surface of a first sapphire substrate; positioning a second sapphire substrate on the titanium layer, forming a face-to-face configuration with the titanium layer between the first and second sapphire substrates; annealing the first and second sapphire substrates in the face-to-face configuration, forming an annealed substrate; and polishing the annealed substrate, forming a polished substrate. The PIC-Ti:Sa laser includes a substrate; a waveguide formed on the substrate, the waveguide including a microring portion; a Ti:Sa layer formed over the microring portion of the waveguide, the Ti:Sa layer and the microring portion of the waveguide forming a microring cavity; and a laser source coupled to the waveguide. Also provided herein are methods of forming a photonic circuit integrated mode-locked Ti:Sa laser.

### CROSS-REFERENCE TO RELATED APPLICATIONS

The present application claims priority under 35 U.S.C. § 119 (e) to U.S. Provisional Patent Application No. 63/519,991, filed Aug. 16, 2023, which application is incorporated herein by reference in its entirety.

### STATEMENT REGARDING FEDERALLY SPONSORED RESEARCH OR DEVELOPMENT

This invention was made with government support under 300 HR0011-20-2-0045 awarded by DARPA. The government has certain rights in the invention.

### BACKGROUND

Since their invention in the 1980s, Ti:Sa lasers have profoundly impacted the photonic industry and research community. Because Ti:Sa crystals are vibronic crystals, their emission bandwidth ranges from 650 to 1100 nm, making them ideal for tunable narrow linewidth lasers and ultra-fast femtosecond lasers. Ti:Sapphire is a must-have equipment for many academic and industrial labs. However, because of the low fluorescence lifetime and low doping concentration, Ti:Sa lasers have a relatively high threshold. As a result, the Ti:Sa lasers rely on complex elaborate stages and are currently restricted in laboratory settings, which significantly drives up the cost of a free space Ti:Sa laser.

Accordingly, there is a need in the art for articles and methods that improve on existing Ti:Sa lasers by reducing the size and cost thereof. The present invention addresses this need.

### SUMMARY

In one aspect, a method of preparing a Titanium:Sapphire (Ti:Sa) wafer includes depositing a titanium layer on a top surface of a first sapphire substrate; positioning a second sapphire substrate on the titanium layer, forming a face-to-face configuration with the titanium layer between the first and second sapphire substrates; annealing the first and second sapphire substrates in the face-to-face configuration, forming an annealed substrate; and polishing the annealed substrate, forming a polished substrate.

In some embodiments, the titanium layer comprises Ti or TiOₓ, wherein x is from 1 to 2. In some embodiments, the step of depositing the titanium layer includes depositing titanium to a thickness of at least 50 nm. In some embodiments, the step of depositing the titanium layer includes depositing titanium to a thickness of 200 nm.

In some embodiments, the annealing step includes a two-step annealing process comprising heating the face-to-face configuration at a first temperature, the first temperature decomposing the titanium layer into a decomposed titanium layer; and heating the face-to-face configuration with the decomposed titanium layer at a second temperature, the second temperature diffusing Ti ions into the sapphire substrates; wherein the annealing process is performed under vacuum. In some embodiments, the titanium layer comprises TiO₂ and the decomposed titanium layer comprises Ti₂O₃. In some embodiments, the first temperature is between about 1750° C. to about 1850° C. In some embodiments, the heating at the first temperature is for between about one hour to about three hours. In some embodiments, the second temperature is between about 1850° C. to about 1950° C. In some embodiments, the heating at the second temperature is for between about one hour to about three hours. In some embodiments, the annealed substrate includes a Ti-diffusion depth of between about 1 μm to about 50 μm.

In some embodiments, the polished substrate includes a roughness of less than 0.2 nm, measured with AFM with Ra.

In some embodiments, the method further includes preparing monolithic photonic circuit integrated Ti:Sapphire laser by growing a thin film on the polished substrate; patterning the thin film, forming a patterned waveguide; depositing an overclad layer over the patterned waveguide; and depositing a heater on the overclad layer. In some embodiments, the thin film is selected from the group consisting of silicon nitride (SiN), aluminum nitride (AlN), lithium niobate (LN), tantala, and a combination thereof. In some embodiments, the step of growing the SiN thin film includes low-pressure chemical vapor deposition (LPCVD) of the SiN thin film. In some embodiments, the step of growing the AlN thin film includes metal organic chemical vapor deposition (MOCVD) of the AlN thin film. In some embodiments, the thin film includes a thickness variation of less than 0.5% across the polished substrate. In some embodiments, the step of patterning the thin film includes patterning through Ebeam lithography or photolithography. In some embodiments, the overclad layer is index matched to a sapphire portion of the patterned waveguide. In some embodiments, the overclad layer comprises SiON or an index matching gel. In some embodiments, the step of depositing the overclad layer includes plasma-enhanced chemical vapor deposition (PECVD) of the overclad layer on the patterned waveguide.

In some embodiments, the method further includes, prior to the step of patterning the thin film, dicing the polished substrate having the thin film deposited thereon into two or more diced substrates. In some embodiments, the subsequent steps of patterning the thin film, depositing the overclad layer over the patterned waveguide, and depositing the heater on the overclad layer are performed separately for each of the two or more diced substrates.

In some embodiments, the method further includes, prior to the annealing step, positioning at least one additional sapphire substrate over the second substrate with an additional titanium layer formed between each of the additional sapphire substrates, forming a multiple face-to-face configuration. In some embodiments, the multiple face-to-face configuration includes nine sapphire substrates and eight titanium layers.

In another aspect, a method of forming a photonic circuit integrated mode-locked Ti:Sa laser includes depositing a thin film on a sapphire substrate; patterning and etching the thin film, the patterning and etching forming a photonic circuit chip; depositing gold on the photonic circuit chip; depositing corresponding gold on a Ti:Sa chip; bonding the photonic circuit chip and the Ti:Sa chip together, forming a bonded chip; and forming a Fabry-Pérot (FP) cavity in the bonded chip, the Fabry-Perot cavity being defined by its reflective surfaces at the chip facets.

In some embodiments, the thin film is selected from the group consisting of silicon nitride (SiN), aluminum nitride (AlN), lithium niobate (LN), tantala, and combinations thereof. In some embodiments, the thin film comprises stoichiometric silicon nitride. In some embodiments, the step of depositing the thin film includes low pressure chemical vapor deposition (LPCVD) of the thin film on the sapphire substrate.

In some embodiments, the bonding step comprises Au—Au bonding or adhesive bonding.

In some embodiments, the reflective surfaces at the chip facets are formed by evaporated gold mirrors or distributed Bragg reflector mirrors.

In some embodiments, the sapphire substrate comprises a diffused sapphire substrate. In some embodiments, the diffused sapphire substrate comprises the polished substrate according to the any of the embodiments disclosed herein.

In some embodiments, the patterning of the thin film comprises electron beam lithography.

In some embodiments, the etching of the thin film comprises reactive ion etching.

In some embodiments, forming the FP cavity includes polishing facets of the bonded chip; transferring graphene; compensating for waveguide dispersion; and evaporating a gold mirror or distributing a Bragg reflector mirror. In some embodiments, the step of compensating for waveguide dispersion comprises evaporating at least one of silicon dioxide and alumina. In some embodiments, prior to the polishing the bonded chip is diced into multiple bonded chips, and the bonded chips are mounted on a side polishing jig. In some embodiments, the transferring of the graphene includes growing the graphene on copper; coating a front side of the graphene with poly(methyl methacrylate) (PMMA); removing a backside of the graphene using oxygen plasma ashing; dissolving the PMMA coated graphene on copper in ammonium sulfate; transferring the dissolved material to water and then to the chip facet; and removing the PMMA using acetone. In some embodiments, the graphene is grown using CVD. In some embodiments, the evaporating the gold mirror includes thermal evaporation or ebeam evaporation.

In a further aspect, a photonic circuit integrated (PIC) Titanium:Sapphire (Ti:Sa) laser includes a substrate; a waveguide formed on the substrate, the waveguide including a microring portion; a Ti:Sa layer formed over the microring portion of the waveguide, the Ti:Sa layer and the microring portion of the waveguide forming a microring cavity; and a laser source coupled to the waveguide. In some embodiments, the substrate comprises sapphire or Ti:Sa. In some embodiments, the Ti:Sa substrate comprises a Ti:Sa wafer formed according to the method of any of the embodiments disclosed herein.

In some embodiments, the waveguide comprises silicon nitride (SiN) or aluminum nitride (AlN). In some embodiments, the waveguide comprises a thickness of between 25 nm and 250 nm.

In some embodiments, the Ti:Sa layer comprises a Ti:Sa wafer formed according to the method of any of the embodiments disclosed herein.

In some embodiments, the laser further includes a dual waveguide coupler. In some embodiments, the dual waveguide coupler includes a pulley coupler phase-matching a pump mode to a ring resonator mode; and a point coupler extracting a lasing mode without disturbing the pump mode.

In some embodiments, the laser source comprises a InGaN laser.

In some embodiments, the optical modes of the pump and gain are less than 1 μm².

In some embodiments, the laser further includes a laser threshold of less than 1 mW.

In some embodiments, the laser further includes a peak emission wavelength of between 650 nm and 1100 nm.

In some embodiments, the PIC-Ti:Sa laser is multi-mode.

In some embodiments, the PIC-Ti:Sa laser is single-mode. In some embodiments, further includes external feedback. In some embodiments, the external feedback comprises a feedback ring. In some embodiments, the microring portion of the waveguide comprises a clockwise lasing mode and the feedback ring comprises a counterclockwise lasing mode. In some embodiments, the external feedback comprises a waveguide distributed Bragg reflector (DBR) grating.

### BRIEF DESCRIPTION OF THE DRAWINGS

FIGS. 1A-C show images and graphs illustrating an existing commercial system and a chip-integrated Ti:Sa laser system on a SiN-on-sapphire photonic platform according to embodiments disclosed herein. (A) Schematic of a commercial free-space Ti:Sa laser. The whole laser system consists of a diode-pumped solid-state (DPSS) laser, a Ti:Sa bow-tie cavity, and a reference cavity for locking. Inset: Emission spectrum of Ti:Sa crystal. (B) Diagram of an integrated chip-based Ti:Sa laser system, including an InGaN pump laser diode, a SiN waveguide loaded with Ti:Sa gain, and an external feedback circuit that includes distributed Bragg reflectors (DBR), actively tuned microring resonators, and integrated photodetectors (PD). (C) On-chip Ti:Sa emission spectrum, with peaks corresponding to microring resonator cavity modes. Inset: Detail of the emission spectrum around 780 nm.

FIGS. 2A-D show a table and graphs illustrating ultralow threshold PIC-integrated Ti:Sa laser. (A) Comparison of mode profiles, effective mode areas and lasing thresholds for state-of-the-art Ti:Sa platforms: free-space cavities, ridge waveguide Ti:Sa lasers, Ti:Sa microfibers, whispering-gallery-mode (WGM) resonators Ti:Sa laser, and PIC-Ti:Sa microring laser. (B) Plot of the lasing threshold and corresponding mode area as taken from a) illustrating the benefits of the PIC-based Ti:Sa laser. The projected theoretical threshold for a heterogencously integrated microring laser with optimal mode area and our experimental waveguide loss (0.4 dB/cm) shows a path for <1 mW pumping. (C) Simulated optical gain as a function of intracavity pump power for integrated Ti:Sa lasers (blue curve) and free space Ti:Sa lasers (red curve). (D) Scaling of the geometrical figure of merit with different SiN waveguide thicknesses.

FIGS. 3A-E show graphs and images illustrating a working principle of integrated Ti:Sa laser and measured results. (A) Ti:Sa laser from an integrated Ti:Sa microring system with strong photon-ion interaction. The SiN microring is idealized as two independent cavities, which are coupled via vibronic Ti ions. Left inset: Measured transmission spectrum of a resonance near the pump wavelength with the Finesse being 31.3. Right inset: Measured transmission spectrum of the optical mode at the lasing wavelength with intrinsic Q of 1.5 million (M) and loaded Q of 0.8 M. (B) Long-pass filtered optical microscope image of the microring resonator in resonance. (C) Optical microscope image of the microring resonator in resonance. (D) Ti:Sa laser spectrum with different peak emission wavelengths. (E) Continuous-wave light-light (L-L) curve of the Ti:Sa laser under continuous-wave optical pumping. The on-chip pumping power and lasing power are estimated by calibrated insertion loss measurements. Two devices with extraction coupling gaps of 200 nm and 400 nm correspond to thresholds of 24.0 mW and 6.8 mW. On-chip lasers can provide a maximum power of 0.4 mW. Inset: L-L curve detail for the device with 6.8 mW threshold.

FIGS. 4A-I show graphs and images illustrating external feedback photonic circuits for single-mode lasing and wavelength selection. (A) Schematic of single microring device. (B) False color scanning electron microscope (SEM) image of the single microring device. (C) Typical lasing spectrum with single-ring geometry. Multiple lasing peaks show up in the wide span of the gain medium. (D) Schematic of a single-mode emission leveraging self-injection locked to an auxiliary ring. As a result of the surface Rayleigh scattering inside the auxiliary ring, there is backscattering from the circulating light which is reflected back into the lasing cavity and triggers self-injection locking. (E) False color SEM image of the coupled ring laser device. (F) Single-mode lasing spectrum via injection-locked emission. (G) Schematic illustrating the influence of external reflector feedback on the selection of the lasing mode. Signals are reflected back to the lasing cavity at the center wavelength of the DBR, providing a seed for the lasing cavity. (H) False color SEM image of the fabricated waveguide DBR. (I) Lasing spectrum at the DBR center wavelength.

FIG. 5 shows a graph illustrating diode-pumped Ti:Sa laser. The emission spectrum measured with different pumping levels, turning from spontaneous emission to lasing. Top inset: Schematic of an InGaN diode-pumped Ti:Sa laser. Bottom inset: L-L curve with the integrated spectrometer signal.

FIGS. 6A-B show a schematic and graph illustrating lasing linewidth measurement. (A) Schematics of the optical setup for photonic circuit integrated Ti:Sa laser. Heterodyne beatnote measurement using commercial Ti:Sa laser (M2laser) allows measurement of laser linewidth using a fast photodetector (PD) and electrical signal analyzer (ESA). (B) Heterodyne beating signal between the on-chip Ti:Sa laser and the reference laser with a full-wave half maximum of 120 KHz.

FIGS. 7A-C show schematics illustrating a process for preparing Ti:Sa wafers and monolithic photonic circuit integrated Ti:Sa lasers. (A) Preparing Ti:Sa wafers. (B) Preparing monolithic photonic circuit integrated Ti:Sa lasers from prepared Ti:Sa wafers. (C) Preparing Ti:Sa wafers and monolithic photonic circuit integrated Ti:Sa lasers.

FIG. 8 shows an image illustrating an example face-to-face annealing process using nine wafers.

FIG. 9 shows an image illustrating the eight wafers of FIG. 8 inside the crucible during annealing.

FIG. 10 shows an image illustrating a diffused run of a box of diffused wafers.

FIG. 11 shows an image illustrating diffusion depth according to an embodiment of the disclosure.

FIG. 12 shows a graph illustrating Ti:Sa emissions.

FIG. 13 shows graphs illustrating the surface morphology of a wafer following diffusion.

FIG. 14 shows an image illustrating the surface roughness of a wafer following polishing.

FIG. 15 shows a graph illustrating SiN thickness of a wafer following LPCVD.

FIG. 16 shows an optical microscope image fabricated device according to an embodiment of the disclosure.

FIG. 17 shows a graph illustrating the intrinsic optical quality factor for the monolithic photonic circuit integrated Ti:Sa lasers.

FIG. 18 shows a schematic illustrating fabrication of a photonic circuit integrated mode-locked Ti:Sa laser.

FIG. 19 shows a graph illustrating the simulated temporal evolution of pulse formation in the photonic circuit integrated mode-locked Ti:Sa laser.

### DETAILED DESCRIPTION

### Definitions

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods and materials are described.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of +20% or +10%, more preferably +5%, even more preferably +1%, and still more preferably +0.1% from the specified value, as such variations are appropriate to perform the disclosed methods.

Ranges: throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

### Detailed Description

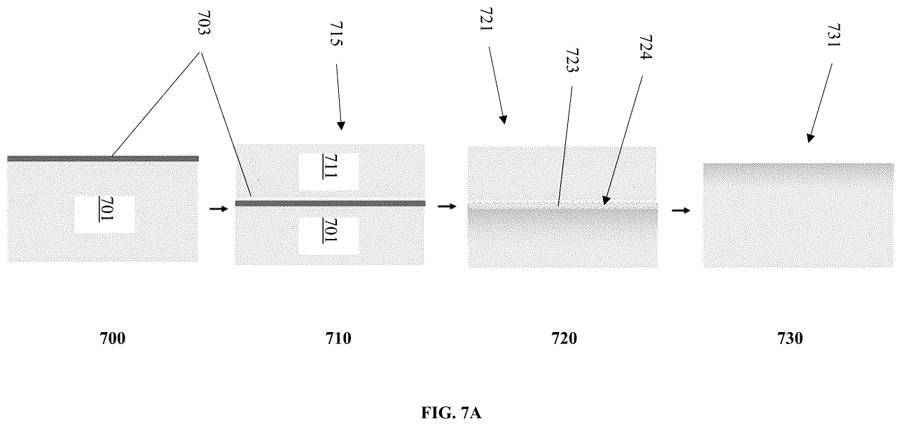

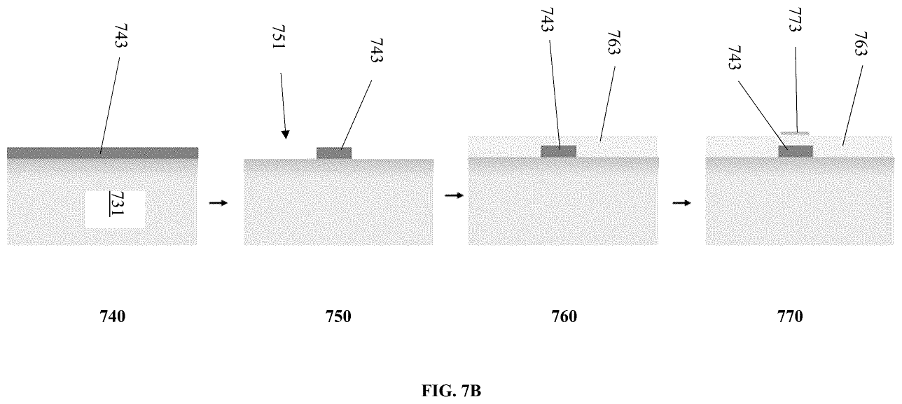

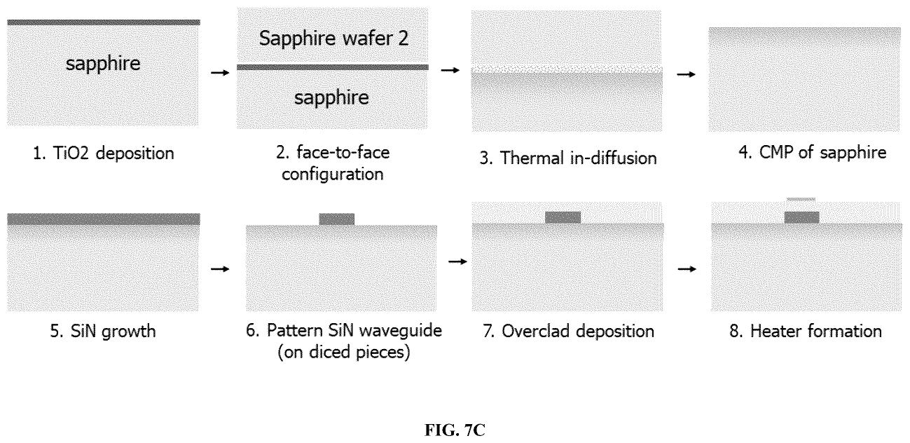

Provided herein are methods of preparing a Titanium:Sapphire (Ti:Sa) wafer. In some embodiments, as illustrated in FIG. 7A, the method includes depositing a titanium layer 703 on a top surface of a first sapphire substrate 701 (700), positioning a second sapphire substrate 711 on the titanium layer 703 (710), annealing the first 701 and second 711 sapphire substrates to form an annealed substrate 721 (720), and polishing the annealed substrate to form the Ti:Sa wafer 731 (730). In some embodiments, the positioning of the second sapphire substrate 711 on the titanium layer 703 (710) includes forming a face-to-face configuration 715 with the titanium layer 703 between the first 701 and second 711 sapphire substrates. In some embodiments, the annealing step (720) includes a two-step annealing process comprising heating the face-to-face configuration 715 at a first temperature, the first temperature decomposing the titanium layer 703 into a decomposed titanium layer 723; and heating the face-to-face configuration 715 with the decomposed titanium layer 723 at a second temperature, the second temperature diffusing Ti ions into the sapphire substrates 724. In some embodiments, the annealing process is performed under vacuum. In some embodiments, the annealing process diffuses titanium ions into sapphire substrates on a wafer scale. Following the annealing, the substrate may be polished (730) (e.g., through chemical mechanical polishing (CMP)) to any suitable roughness for forming the Ti:Sa wafer. Suitable roughness includes, but is not limited to, less than 0.2 nm. In some embodiments, the roughness is measured with AFM with Ra.

The titanium layer 103 may include any suitable titanium containing composition deposited to any suitable thickness. Suitable titanium containing compositions include, but are not limited to, Ti or TiOₓ, where x is between 1 and 2. In some embodiments, after diffusion the x in TiOₓ is 1.5. Suitable thicknesses of the titanium layer include, but are not limited to, at least 50 nm, at least 100 nm, between 50 nm and 300 nm, between 50 nm and 200 nm, or any suitable combination, sub-combination, range, or sub-range thereof. As will be appreciated by those skilled in the art, to composition of the decomposed titanium layer will depend upon the composition of the deposited titanium layer. For example, in some embodiments, the titanium layer comprises TiO₂ and the decomposed titanium layer comprises Ti₂O₃.

The annealing steps may be performed at any suitable temperature and/or for any suitable duration to provide a desired Ti-diffusion depth. Suitable Ti-diffusion depths include, but are not limited to, up to about 50 μm, up to about 40 μm, up to about 30 μm, between about 1 μm and about 50 μm, between about 1 μm and about 40 μm, between about 1 μm and about 30 μm, between about 5 μm and about 40 μm, between about 10 μm and about 40 μm, or any suitable combination, sub-combination, range, or sub-range thereof. As will be appreciated by those skilled in the art, in some embodiments, the temperature and duration for providing the desired Ti-diffusion depth is based upon the composition of the deposited titanium layer. For example, in some embodiments, the first step includes heating the face-to-face configuration to a first temperature of between about 1750° C. and about 1850° C. for between about 1 hour to about 3 hours. In some embodiments, the second step includes heating the face-to-face configuration with the decomposed titanium layer to a second temperature of between about 1850° C. and about 1950° C. for between about 1 hour to about 3 hours. In some embodiments, the annealing is performed under a reduction (e.g., oxygen deficient) environment.

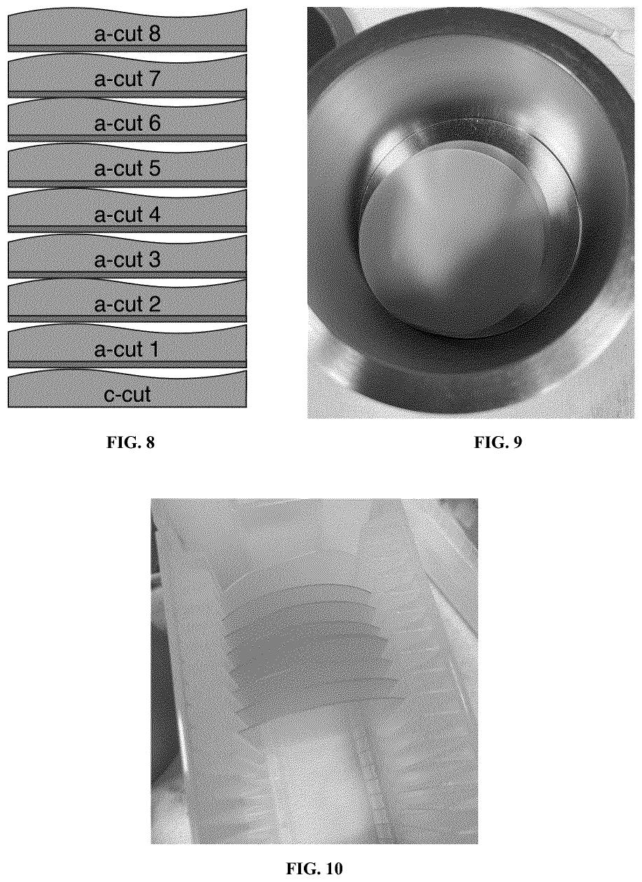

In some embodiments, prior to the annealing step, the method includes positioning at least one additional sapphire substrate over the second substrate with an additional titanium layer formed between each of the additional sapphire substrates (FIG. 8). The positioning of the at least one additional sapphire substrate over the second substrate forms a multiple face-to-face configuration. The multiple face-to-face configurations may include any suitable number of sapphire substrates and titanium layers. For example, in some embodiments, the multiple face-to-face configuration includes nine sapphire substrates and eight titanium layers. The face-to-face annealing according to any of the embodiments disclosed herein provides a highly cost-effective process to produce high-quality large-size Ti:Sa wafers. Additionally or alternatively, in some embodiments, and in contrast to furnace grown Ti;Sa, the methods disclosed herein permit localized sectioned control. For example, patterning the TiO₂ through photolithography prior to diffusion of Ti-Sa provides localized gain section control.

Also provided herein are methods of forming photonic circuit integrated Ti:Sa lasers. The photonic circuit may be integrated through monolithic or heterogeneous integration. In some embodiments, thermal diffusion provides a scalable method for monolithic gain integration. For example, in some embodiments, as illustrated in FIG. 7B, a method of preparing a monolithic photonic circuit integrated Ti:Sa laser includes providing or forming the Ti:Sa wafer 731 as disclosed herein (e.g., FIG. 7A), then growing a thin film 743 on the polished substrate (740); patterning the thin film (750), forming a patterned waveguide 751; depositing an overclad layer 763 over the patterned waveguide 751 (760); and depositing a heater 773 on the overclad layer (770). FIG. 7C shows one example of preparing a monolithic photonic circuit integrated Ti:Sa laser including formation of the Ti:Sa wafer 731.

The thin film includes any suitable material for patterning over the polished substrate. Suitable thin films include, but are not limited to, silicon nitride (SiN), aluminum nitride (AlN), or a combination thereof. As will be appreciated by those skilled in the art, the thin film may be grown by any suitable method depending upon the thin film material. For example, in some embodiments, the SiN thin film is deposited through low-pressure chemical vapor deposition (LPCVD). In some embodiments, the AlN thin film is grown through metal organic chemical vapor deposition (MOCVD). In some embodiments, the thin film includes a thickness variation of less than 0.5% across the polished substrate. Following the growing step, the thin film may be patterned by any suitable method, such as, but not limited to, Ebeam lithography or photolithography.

In some embodiments, the overclad layer is index matched to a sapphire portion of the patterned waveguide. For example, in some embodiments, the overclad layer includes SiON or an index matching gel with similar index to sapphire. The overclad layer may be deposited on the patterned waveguide through any suitable method. For example, in some embodiments, the step of depositing the overclad layer includes plasma-enhanced chemical vapor deposition (PECVD) of the overclad layer on the patterned waveguide.

In some embodiments, prior to the step of patterning the thin film, the method includes dicing the polished substrate having the thin film deposited thereon into two or more diced substrates. In some embodiments, the subsequent steps of patterning the thin film, depositing the overclad layer over the patterned waveguide, and depositing the heater on the overclad layer are performed separately for each of the two or more diced substrates.

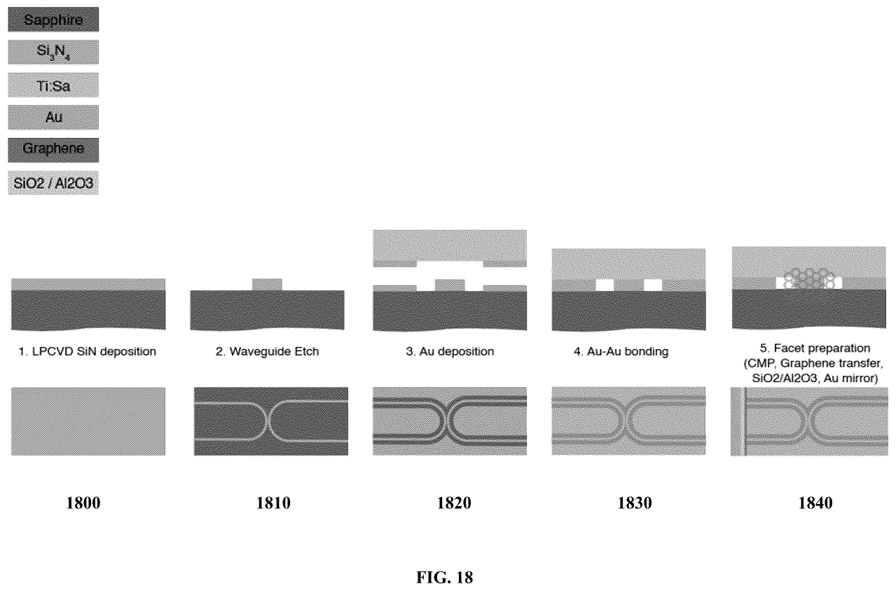

Additionally or alternatively, in some embodiments, heterogeneous integration is achieved by plasma-activated flip-chip bonding. In some embodiments, the flip-chip bonding is between a Ti:Sa crystal and a sapphire-based photonic platform. In some embodiments, the method includes forming a photonic circuit integrated mode-locked Ti:Sa laser. In some embodiments, as illustrated in FIG. 18, the method includes depositing a thin film on a sapphire substrate (1800); patterning and etching the thin film to form a photonic circuit chip (1810); depositing gold on the photonic circuit chip and depositing corresponding gold on a Ti:Sa chip (1820); bonding the photonic circuit chip and the Ti:Sa chip together to form a bonded chip (1830); and forming a Fabry-Pérot (FP) cavity in the bonded chip (1840), the Fabry-Perot cavity being defined by its reflective surfaces at the chip facets.

The sapphire substrate includes any suitable sapphire substrate, such as, but not limited to, a diffused sapphire substrate, the polished substrate according to any of the embodiments disclosed herein, or any other suitable sapphire substrate. The thin film includes any suitable material for depositing on and patterning/etching over the sapphire substrate. For example, in some embodiments, the thin film includes stoichiometric silicon nitride, AlN, LN, or tantala. Additionally, the thin film may be deposited by any suitable method, such as, but not limited to low pressure chemical vapor deposition (LPCVD) of stoichiometric silicon nitride, metal-organic chemical vapor deposition (MOCVD) of AlN, bonding of LN, or sputtering of tantala. Following deposition, the thin film may be patterned and/or etched to form a photonic circuit chip by any suitable method. Suitable methods of patterning include, but are not limited to, photolithography and electron beam lithography. Suitable methods of etching include, but are not limited to, reactive ion etching. Once formed, the photonic circuit chip and the Ti:Sa chip may be bonded together through any suitable method, such as, but not limited to, Au—Au bonding, plasma activated direct bonding, or BCB adhesive bonding.

In some embodiments, the reflective surfaces at the chip facets are formed by evaporated gold mirrors or distributed Bragg reflector mirrors. In some embodiments, forming the FP cavity includes polishing facets of the bonded chip; transferring graphene; compensating for waveguide dispersion; and evaporating a gold mirror or distributing a Bragg reflector mirror. In some embodiments, polishing the facets of the bonded chip includes first dicing the chips with a laser cutter and then mounting on a side polishing jig for facet polishing. In some embodiments, the step of transferring graphene includes growing the graphene on copper (e.g., through CVD), coating the front side of graphene with PMMA, removing the backside graphene (e.g., using oxygen plasma ashing), and dissolving the PMMA/Graphene/Cu in ammonium sulfate. Next, the dissolved PMMA/Graphene/Cu is transferred to water, and then transferred to the chip facet, after which the PMMA is removed using acetone. In some embodiments, the step of compensating for waveguide dispersion includes evaporating at least one of silicon dioxide and alumina. In some embodiments, the gold mirror is formed by any suitable method of evaporation, such as, but not limited to, thermal evaporation or ebeam evaporation.

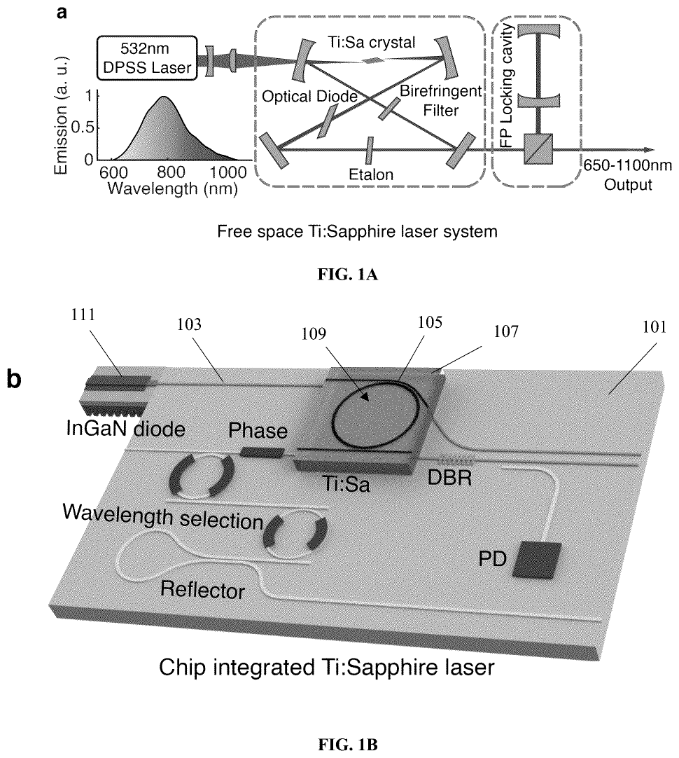

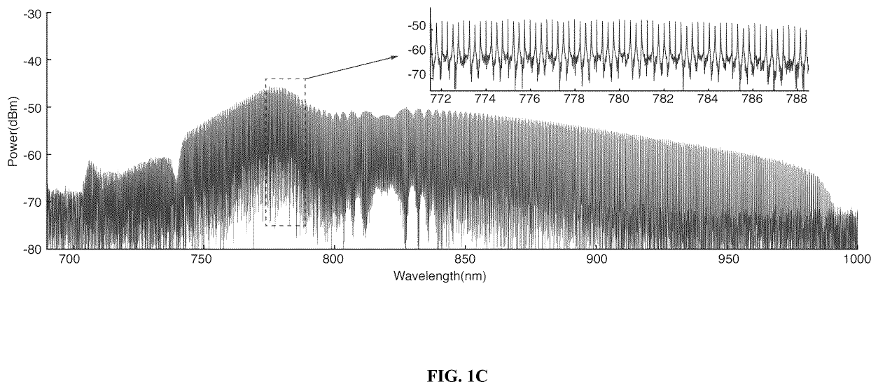

Further provided herein is a photonic circuit integrated (PIC) Titanium:Sapphire (Ti:Sa) laser. In some embodiments, as illustrated in FIG. 1B, the PIC Ti:Sa laser comprises a substrate 101; a waveguide 103 formed on the substrate 101, the waveguide 103 including a microring portion 105; a Ti:Sa layer 107 formed over the microring portion 105 of the waveguide 103, the Ti:Sa layer 107 and the microring portion 105 of the waveguide 103 forming a microring cavity 109; and a laser source 111 coupled to the waveguide 103. In some embodiments, the substrate 101 includes sapphire or Ti:Sa. In some embodiments, the Ti:Sa substrate includes a Ti:Sa wafer formed according to one or more of the methods disclosed herein. In some embodiments, the laser formed according to one or more of the embodiments disclosed herein (e.g., heterogeneously integrating a Ti:Sa gain medium onto a SiN-on-sapphire photonic platform with pump signal cavity enhancement) provides a reduced lasing threshold of less than 10 mW. For example, in some embodiments, the laser provides narrow-linewidth lasing from 730 nm to 830 nm with a linewidth of 120 KHz.

In some embodiments, the waveguide comprises silicon nitride (SiN), aluminum nitride (AlN), LN, or tantala. The waveguide is deposited by any suitable method and includes any suitable thickness. Suitable methods include, but are not limited to, LPCVD. Suitable thicknesses include, but are not limited to, between 50 nm and 250 nm. In some embodiments, the Ti:Sa layer includes a Ti:Sa wafer formed according to one or more of the methods disclosed herein. For example, in some embodiments, a SiN waveguide is grown on a first Ti:Sa wafer, and a second Ti:Sa wafer is positioned over the SiN waveguide to form a top cladding, with both the first and the second Ti:Sa wafers being formed according to one or more of the embodiments disclosed herein. In some embodiments, the use of the second Ti:Sa wafer instead of an existing cladding, such as SiON, increases (e.g., doubles) the optical gain. Additionally or alternatively, in some embodiments, a heater or active χ2 material (e.g., AlN and/or lithium niobate) is integrated into a bottom-cladded geometry, providing active control of the laser. The bottom-cladded Ti:Sa laser may be used in integrated visible photonics.

In some embodiments, the PIC-Ti:Sa laser further includes a dual waveguide coupler. In some embodiments, the dual waveguide coupler includes a pulley coupler 301 phase-matching a pump mode to a ring resonator mode, and a point coupler 303 extracting a lasing mode without disturbing the pump mode. In some embodiments, the laser source of the PIC-Ti:Sa laser includes a InGaN laser. For example, a GaN laser diode may be used to provide turn-key Ti:Sa operation, or GaN can be integrated into the photonic chip to provide everything on one chip. In some embodiments, the pump laser integration scheme opens a reliable pathway for broadband and tunable lasing in next-generation active-passive integrated visible photonics. Additionally or alternatively, in some embodiments, the InGaN laser provides a reduced size as compared to argon lasers used in existing systems. Although discussed herein primarily with respect to an InGaN laser, as will be appreciated by those skilled in the art, the disclosure is not so limited and includes other lasers, such as other solid-state crystal lasers and rare-earth ion lasers.

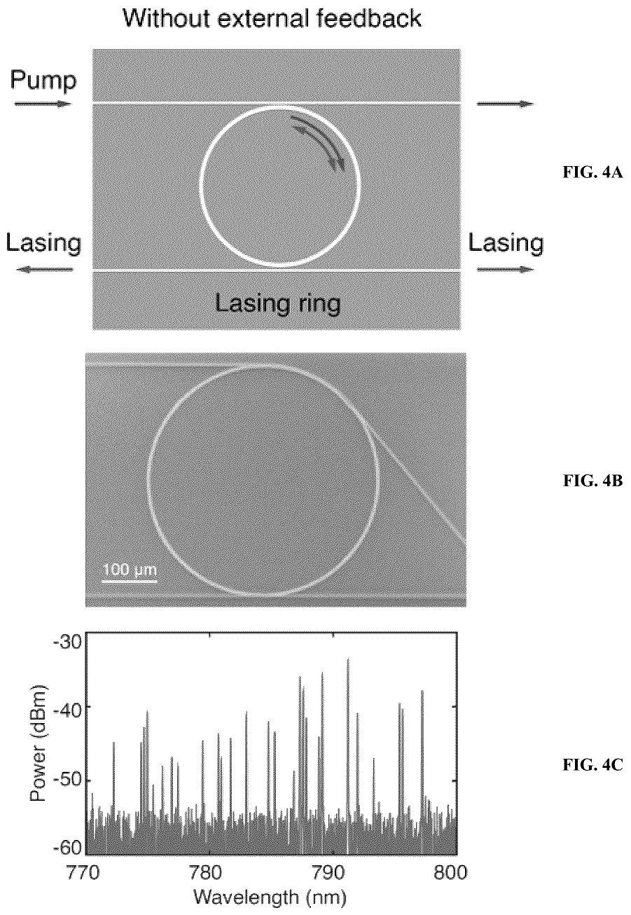

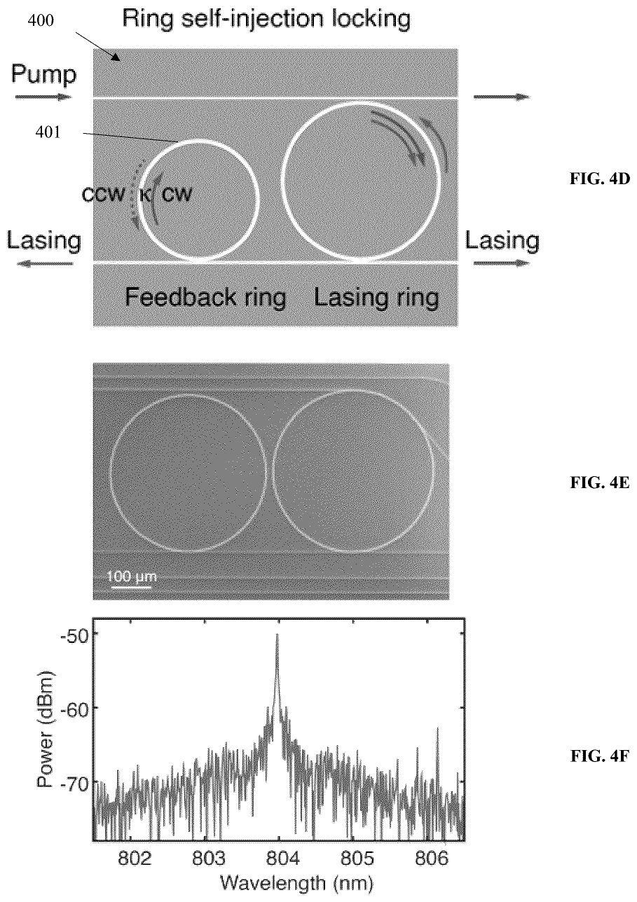

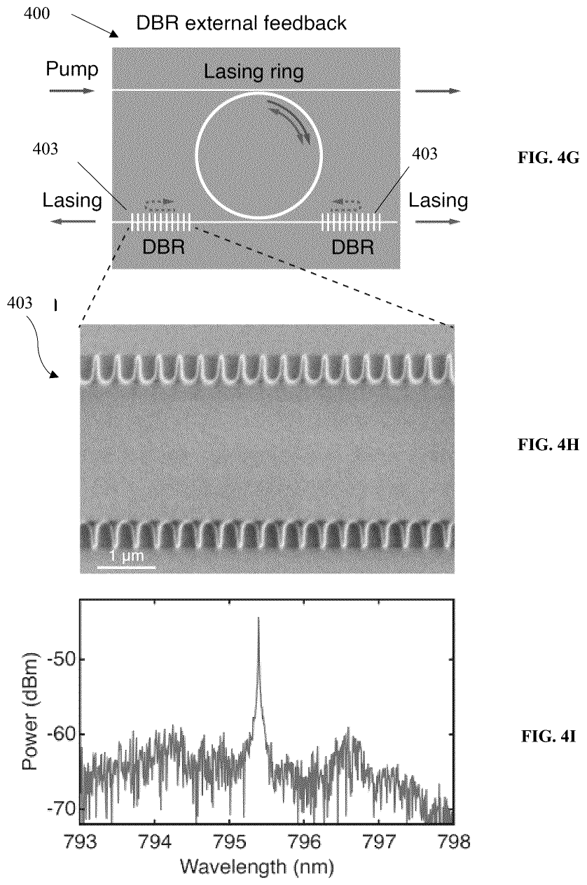

The PIC-Ti:Sa laser may be single mode or multi-mode. In some embodiments, the optical modes of the pump and gain are less than 1 μm². In some embodiments, the PIC-Ti:Sa laser includes a laser threshold of less than 1 mW. In some embodiments, the PIC-Ti:Sa laser includes a peak emission wavelength of between 650 nm and 1100 nm. In some embodiments, the PIC-Ti:Sa laser includes external feedback 400 (FIGS. 4D-I). In some embodiments, the external feedback 400 includes a feedback ring 401 (FIGS. 4D-F) and/or a waveguide distributed Bragg reflector (DBR) grating 403 (FIGS. 4G-I). In some embodiments, the microring portion of the waveguide comprises a clockwise lasing mode and the feedback ring comprises a counterclockwise lasing mode. Additionally or alternatively, in some embodiments, a saturable absorber is integrated onto the Ti:Sa laser chip to facilitate pulsed laser operation.

The articles and methods disclosed herein provide Ti:Sa miniaturization by combining Ti:Sa gain with a photonic chip. This miniaturization reduces the laser's power consumption and permits the formation of chip-sized systems having a volume of less than one cubic centimeter. Additionally, the emission spectrum of Ti:Sa covers a wide range of wavelengths inaccessible to conventional semiconductor lasers. Laser sources that emit at ion transition wavelengths such as rubidium Rydberg at 780 nm, diamond quantum memory emitting at 737 nm, and strontium transition at 813 nm provide a solution for probing and manipulating atoms and ions on-chip. Accordingly, the laser according to one or more of the embodiments disclosed herein facilitates the production of integrated atomic photonic devices such as, but not limited to, atomic clocks, portable sensors, visible light communication devices, quantum computing, other devices for trapping ions, other devices for controlling ions qubits, or combinations thereof. Furthermore, the co-integration of active components that facilitate intensity control and switching provide all the functionality needed for such applications. Other suitable uses include, but are not limited to, autonomous vehicles (e.g., detecting and ranging light, displaying and projecting images), virtual reality, augmented reality, other consumer markets that provide pass-through or glanceable digital content, and/or other uses relying on chip-scale light sources at visible wavelengths.

Without wishing to be bound by theory, the laser according to one or more of the embodiments disclosed herein is believed to be the first titanium-doped sapphire laser integrated into a chip-scale photonic circuit, which produces the broadest gain spectrum ever by an on-chip platform. For example, in some embodiments, the heterogenous integration of the Ti:Sa gains onto a SiN-on-sapphire photonic platform with simultaneous pump-signal cavity enhancement provides an ultra-low threshold (e.g., <10 mW). In contrast to existing free space systems, where a laser cavity consists of a bow-tie cavity with a Ti:Sa gain crystal, the SiN microring resonator of the articles disclosed herein replaces the aforementioned cavity with strong optical-to-gain coupling. The thin SiN provides a low-confined mode with sufficient ion overlap with the crystal. Additionally, SiN photonic integrated circuits provide active tuning, wavelength selection, and locking functionalities.

Those skilled in the art will recognize, or be able to ascertain using no more than routine experimentation, numerous equivalents to the specific procedures, embodiments, claims, and examples described herein. Such equivalents are considered to be within the scope of this invention and covered by the claims appended hereto.

It is to be understood that wherever values and ranges are provided herein, all values and ranges encompassed by these values and ranges, are meant to be encompassed within the scope of the present invention. Moreover, all values that fall within these ranges, as well as the upper or lower limits of a range of values, are also contemplated by the present application.

The following examples further illustrate aspects of the present invention. However, they are in no way a limitation of the teachings or disclosure of the present invention as set forth herein.

### EXAMPLES

### Example 1

Compact narrow-linewidth visible lasers are pivotal components for optical sensing, metrology, and communications, as well as precision atomic and molecular spectroscopy. With an emission bandwidth approaching an octave, titanium-doped sapphire (Ti:Sa) lasers are the preeminent tool for producing solid-state lasing across visible and near-infrared bands. However, today's commercial Ti:Sa laser systems require high pump power and rely on expensive tabletop components, which restrict them to laboratory settings. In this example, we present a photonic circuit integrated Ti:Sa laser that combines the Ti:Sa gain medium with a silicon-nitride-on-sapphire integrated photonics platform, resulting in high portability with minimal power consumption. We demonstrate Ti:Sa lasing from 730 nm to 830 nm by tightly confining the pump and lasing modes in a single microring resonator, reducing the lasing threshold by orders of magnitude down to 6.8 mW when compared to the free space Ti:Sa lasers. Due to the low threshold, turn-key Ti:Sa laser operation is achieved by leveraging a commercially available indium gallium nitride (InGaN) pump diode. Our photonic circuit integrated Ti:Sa, despite being a prototype, opens a reliable pathway for broadband tunable lasers in next-generation active-passive integrated visible photonics.

### INTRODUCTION

Since their invention in 1982, Ti:Sa lasers have enabled a plethora of applications in fundamental physics, chemical spectroscopy and biological research. The Ti:Sa as a gain medium offers numerous benefits and enormous flexibility; due to the strong coupling between the vibrational state of a sapphire host and the active titanium ions, Ti:Sa has one of the widest emission spectrum among all laser systems, with wavelengths ranging from 650 nm to 1100 nm, spanning from the red to the near-infrared (NIR). Using a single Ti:Sa crystal, commercial systems provide a narrow linewidth laser with about 400 nm (i.e., ˜190 THz) tuning range. The ultra-broadband gain of Ti:Sa also leads to the generation of femtosecond mode-locked pulses and propels the rapid development of optical frequency combs. All these properties make Ti:Sa lasers stand out among laser technologies. However, commercial Ti:Sa lasers are constructed from bulky free-space components which require a series of elaborate stages, such as a diode-pumped solid-state excitation laser, a Ti:Sa bow-tie laser cavity, and a reference locking cavity (FIG. 1A). Because of the short lifetime of excited states (i.e., 3.2 μs), the low fluorescent ion concentration (i.e., <1 at %), and the residue absorption at near-IR generated during crystal growth, the Ti:Sa laser threshold is comparably high.

Miniaturization of the Ti:Sa gain medium has the potential to allow greater modal confinement of the pump, resulting in a stronger modal excitation of the active medium and a lasing threshold reduced by orders of magnitude as compared to the bulk. A number of effective methods have been used to create higher mode confinement in Ti:Sa structures, including channel waveguides by thermal diffusion, pulsed laser deposition with ridge formation, laser-written waveguides, and crystal microfibers. However, due to the small index contrast and the large size of the guided mode, the lasing threshold remained close to 100 mW. Recently, by precision polishing a Ti:Sa crystal, an ultra-high quality-factor (Q-factor=50 million) whispering gallery mode (WGM) resonator was demonstrated with a successful reduction of lasing threshold down to 14.2 mW, highlighting the benefits of high-Q WGM cavities. Nevertheless, free-space optics remained necessary for addressing these resonators. Meanwhile, thanks to the reduced mode size and large index contrast, a significant performance enhancement is expected by incorporating the Ti:Sa gain media directly on a planar photonic circuit, providing on-chip functionalities and control with no moving parts. FIG. 1B illustrates a conceptional platform that substitutes the pump laser, Ti:Sa cavity, and external locking cavity in conventional table-top systems with a compact InGaN pump laser diode, a waveguide microring resonator lasing cavity, and an integrated sapphire-based photonic feedback circuit chip.

Here, we present an integrated Ti:Sa laser directly bridging the Ti:Sa active gain medium and the passive photonic integrated circuits (PICs), demonstrating a record low threshold for Ti:Sa lasing. We adopt a waveguide design with tight mode confinement to provide simultaneous cavity enhancement for the pump and the Ti:Sa signals within a compact 200-μm radius microring resonator cavity. Multi-mode and single-mode lasing at the Ti:Sa peak gain is obtained in different configurations of the PIC. The on-chip waveguide coupled Ti:Sa emission spans more than half an octave from 700 nm to 950 nm, thus laying down the foundation of enhanced lasing span and tunability (FIG. 1C). Benefiting from the intrinsic low lasing threshold of the integrated Ti:Sa, a commercial InGaN laser is exploited to enable turn-key Ti:Sa laser operation. A fully integrated Ti:Sa laser represents a versatile scientific and engineering tool for a wide variety of applications including atomic clocks, integrated quantum photonics, spectroscopy, visible light communication, Lidar, augmented reality, and more.

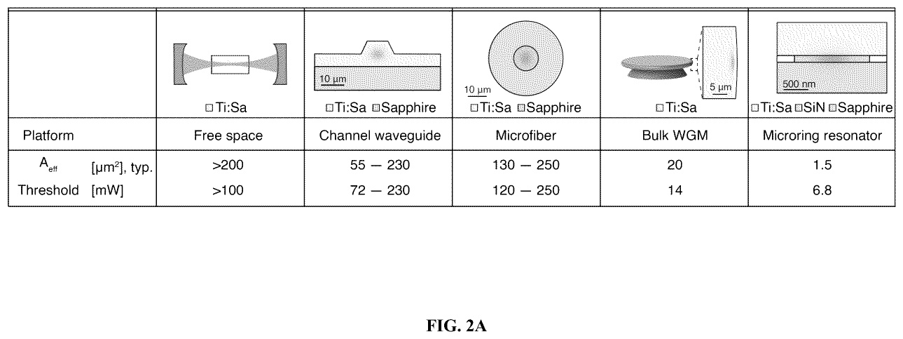

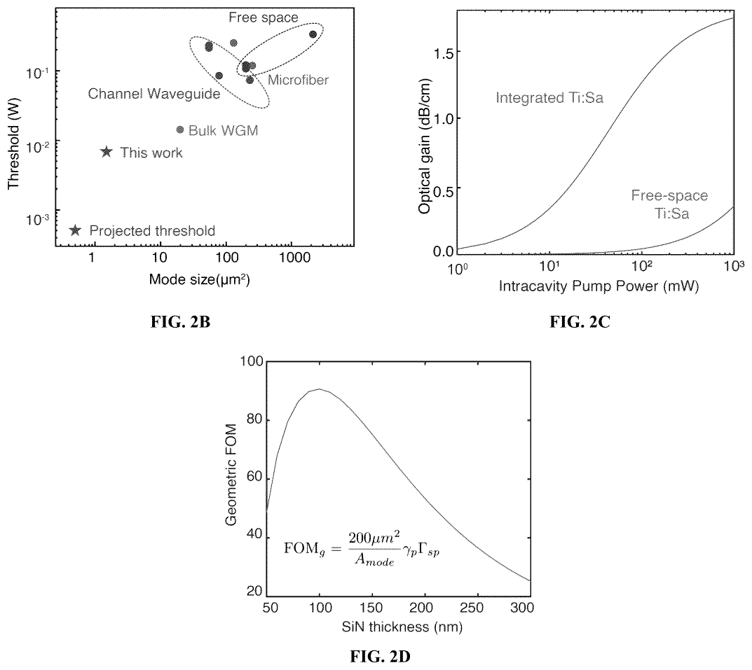

Compared to semiconductors and rare-earth-ion-based gain media, Ti:Sa is known to have low gain due to its short lifetime of excited states and low ion doping concentration, which lead to the demand for a high pump power. Ti:Sa inside free-space cavities also has a large mode area, constrained by the Gaussian beam size at the confocal distance of the focusing optics. Commercial free-space Ti:Sa lasers usually have a mode area larger than 200 μm² and consequently have a watt-level threshold. In aggressively optimized free space Ti:Sa lasers using relatively high Ti concentration and low-transmission output optics, the laser system can reach as low as 119 mW threshold. The optical mode size of the reported waveguide Ti:Sa lasers and microfibers are smaller compared to free-space modes. With a mode size in the range of 55-230 μm², the threshold has been reduced to 72-230 mW. Despite this, the thresholds remain largely constrained by weak index contrast and weak mode confinement. Polishing and reshaping the Ti:Sa crystal into a whispering gallery mode resonator reduced the mode area to 20 μm² with low scattering loss (Q-factor of 50 million at lasing wavelength), resulting in a dramatic reduction of the threshold down to 14.2 mW. In our design of the photonic circuit integrated Ti:Sa laser we address the low index contrast and mode confinement by utilizing thin-film silicon nitride (SiN) waveguides on a sapphire-based platform. The optical modes of the pump and gain are reduced to below 1 μm², making it possible to achieve local population inversion with low pump power, and an estimated threshold below 1 mW. While the device demonstrated in this work achieves a laser threshold of 6.8 mW (threshold power density: 270.6 W/cm²), further refinement of the device geometry and loss reduction are expected to bring the experimental value closer to the theoretical one. A plot summarizing and comparing the state-of-the-art Ti:Sa lasers is shown in FIGS. 2A-B.

FIG. 2C shows the calculated optical gain at 780 nm for the free-space Ti:Sa and integrated Ti:Sa lasers at varying intracavity pump powers. The optical gain in the photonic circuit integrated Ti:Sa is one order of magnitude higher than the free-space Ti:Sa, especially at low pump power. To achieve a gain of 0.2 dB/cm within a free-space Ti:Sa laser, the intracavity power must be over 300 mW. In contrast, with tens of milliwatts of power, the photonic circuit integrated Ti:Sa provides an optical gain of 0.4 dB/cm. As the pump mode is on resonance in the microring, the on-chip threshold is further reduced by the pump cavity enhancement. To minimize the laser threshold and maximize the output power, here we introduce a device design figure of merit: FOMg=200 μm²/A_{mode} γₚΓsp, where γₚ is the pump mode confinement factor, Γₛₚ is the pump-signal overlap factor and A_{mode} is the mode area for pump. The FOM describes the estimated geometrical advantage in the PIC platform compared to free-space counterparts. For aggressively optimized Ti:Sa free space lasers the geometrical FOM is close to 1, whereas for a typical commercial laser the FOM is 0.2. In the PIC-based Ti:Sa laser system, the geometrical FOM approaches 100, suggesting that a 500 times reduction in the laser threshold is expected. In FIG. 2D, we show that a SiN waveguide with a thickness of 100 nm is optimal to reach a small mode area, large signal-pump overlap factor, and significant pump confinement factor, leading to a geometric FOM of 90. In our experiment, we choose the thickness to be 150 nm considering the trade off between the radiation loss and device compactness.

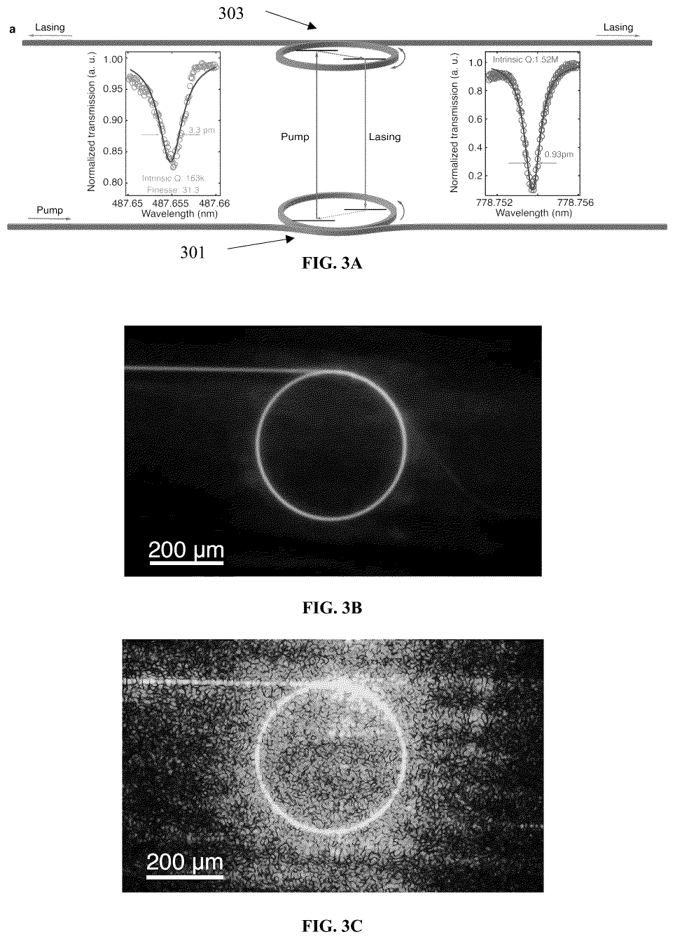

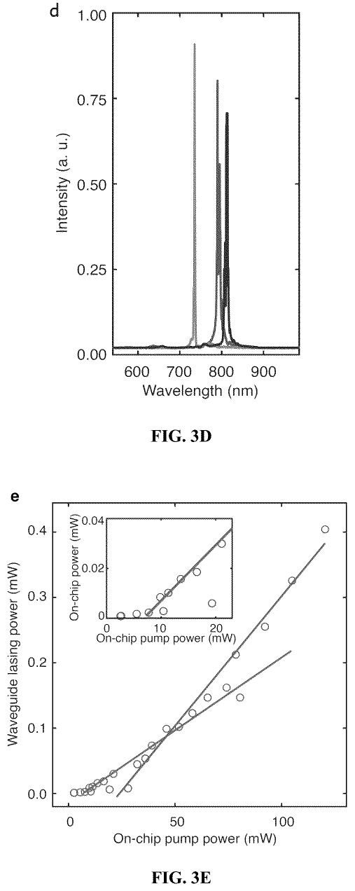

The on-chip implementation of the Ti:Sa laser is idealized in FIG. 3A, where two independent cavities (pump and signal) are coupled by the Ti:Sa's four-level systems. The lasing operation is realized when the population inversion occurs near the optical modes of the microring resonator. Thus, by achieving the dual resonance condition of the lasing cavity, the photonic circuit integrated Ti:Sa laser design aims at a high operation efficiency. The wide spectral separation between the blue-to-green pump mode and the red-to-NIR lasing mode, as well as the strong pump mode absorption in the cavity, pose a great challenge for designing an efficient coupler for both pump and lasing wavelengths. From a cavity design perspective, with a critically-coupled or over-coupled pump mode, Ti ions are effectively excited in the microcavity, while an under-coupled lasing cavity has a lower lasing threshold and higher intracavity power build-up factors. Therefore, we use a dual waveguide coupler design to satisfy both coupling requirements: a pulley coupler ensures phase-matching of the pump mode to the ring resonator mode, and a point coupler enables extraction of the lasing mode without disturbing the pump mode. Here, to reduce the back coupling of the lasing mode through the pulley coupler pump waveguide, the width of the waveguide is designed to be sufficiently narrow to sustain single mode operation at the pump but not able to support the longer wavelength Ti:Sa lasing modes.

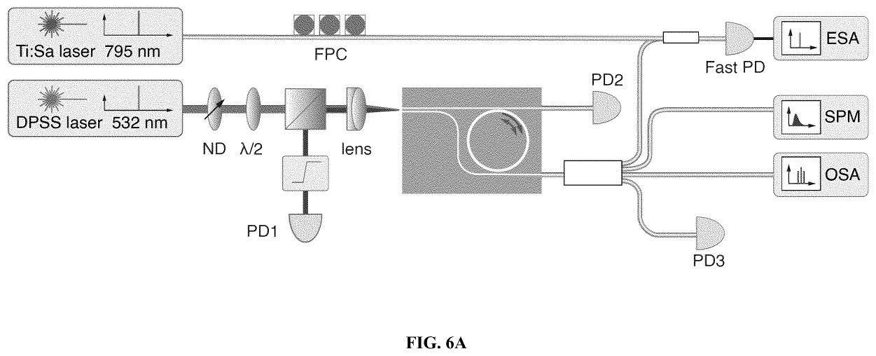

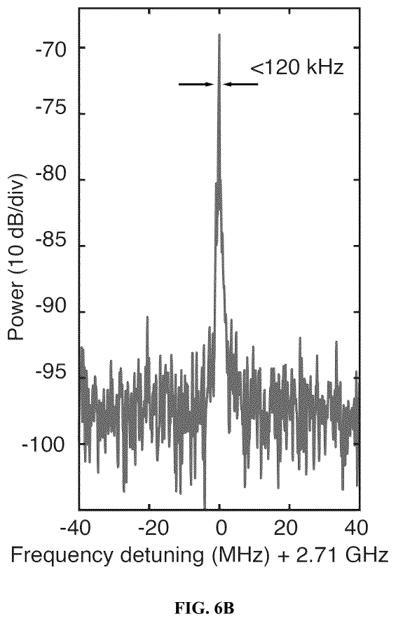

We measure the optical loss at the pump and lasing wavelength separately. Since a 532-nm tunable laser is not available, we choose to characterize the microring finesse at around 488 nm, which is nearly 33 and corresponds to a cavity enhancement factor of 5.3 (FIG. 3A left inset). It is expected that the pump enhancement is stronger at 532 nm because of weaker Ti:Sa absorption and lower SiN waveguide loss. The resulting Ti:Sa lasing mode has a loaded quality factor of 800,000 and an intrinsic quality factor of 1.52 million, corresponding to 0.4 dB/cm propagation loss and 0.8 dB/cm loaded loss (FIG. 3A 135 right inset). Since the optical gain must be greater than the loaded propagation loss for it to reach the lasing threshold, we estimate a minimum budget of 30 mW intracavity power and less than 10 mW on-chip coupled power (FIG. 2C). The details of the measurement setup can be found in the method section and FIG. 6A. FIGS. 3B-C shows the optical microscope image of the lasing mode and pump mode on resonance. FIG. 3C shows the optical microscope image when the microring resonator is tuned into resonance and kept near critically coupled condition. FIG. 3B shows the long pass filtered optical microscope image of the microring resonator showing lasing action. During testing, the pump is tuned into resonance condition by changing the chip temperature.

The fabricated Ti:Sa lasers provide a wide range of emission wavelengths, with peaks between 730 nm and 830 nm. FIG. 3D shows the lasing spectrum recorded by a spectrometer for multiple devices with different lasing wavelength, extraction coupling conditions, and temperature of operation. The broadband coupling of the point coupler and the absence of external feedback circuits lead to lasing at various different wavelengths within the Ti:Sa gain region. FIG. 3E illustrates the continuous wave light-light (L-L) curve of two devices with different lasing waveguide extraction gaps of 200 nm and 400 nm. A larger extraction gap results in a lower coupling loss and a higher loaded Q of the Ti:Sa signal, which leads to a lower threshold. The inset illustrates the performance of the under-coupled device with an extraction gap of 400 nm (blue curve) and an ultra-low threshold of 6.8 mW. This value is similar to the theoretical threshold of 5.6 mW (FIG. 2C) and corresponds to a peak wavelength emission of 805 nm and an operating temperature of 41.5° C. This ultra-low lasing threshold represents a novel pathway for minimal power consumption in Ti:Sa micro lasers. Further improving the waveguide loss, a larger optical mode confinement factor, and a smaller mode size could further reduce the threshold to below 1 mW, which will have a great benefit for portable Ti:Sa lasers.

For the current stage of development of our prototype, the slope efficiency still has room for improvement. The theoretical slope efficiency can be expressed as: ηₛ˜λₚ/λₛκₑₓ/κₑₓ+κᵢₙη_{q}γₚΓₛₚ, where κₑₓ is waveguide-microring coupling rate, κᵢₙ is the round-trip loss rate inside the microring resonator, η_{q} is the quantum efficiency with a typical value between 0.4 and 0.9, γₚ denotes the pump mode confinement factor, and Γₛₚ is the pump-signal overlap factor. By devising a stronger ring-to-waveguide coupling (κₑₓ), the device with an extraction gap of 200 nm (FIG. 3E red curve) produces a higher slope efficiency. A higher lasing threshold of 24 mW it is recorded and expected due to the increased coupling strength. Nonetheless, the route for combining the benefits of both an ultra-low threshold and a greater slope efficiency, relies on reducing waveguide loss (κᵢₙ), and engineering the optical mode geometry towards a higher pump mode confinement factor (γₚ) and a larger pump-signal overlap (Γₛₚ).

A number of applications require specific lasing wavelengths. In free-space Ti:Sa lasers, the wavelength selection is controlled by an etalon and a high Finesse Fabry-Pérot (FP) cavity that fine-tunes and locks to the desired mode. In other forms of miniaturized Ti:Sa lasers, lasing wavelength selection and single-mode operation are achieved by selective coupling and diffraction of free-space optical elements (e.g., grating, prism). In the PIC-based Ti:Sa laser, the typical single ring lasing spectrum is multi-mode as illustrated in FIGS. 4A-C and lasing will occur whenever the gain is greater than the cavity loss. This is due to the absence of external feedback and the broadband Ti:Sa gain spectrum. However, single-mode emission of the photonic circuit integrated Ti:Sa laser can be achieved by adding an external feedback. In contrast to semiconductor lasers with a linewidth enhancement factor of 3-5, an integrated Ti:Sa laser can have a narrow linewidth with a near-zero linewidth enhancement factor thus offer linewidth lasing. As a proof of principle, though the measurement is done when the laser is operating in a multi-mode regime, we measured the linewidth by heterodyne beating our on-chip laser with a commercial Ti:Sa laser. The intrinsic linewidth of the beat signal is narrower than 120 kHz (FIG. 6B), with a resolution limited by our instruments.

To generate a single-mode laser, the threshold conditions in the Ti:Sa cavity, such as loss and gain have to be engineered. We first introduce a feedback microring resonator coupled to the lasing ring resonator, as shown in FIG. 4D. The purpose of this feedback ring is to reduce the loss of a singular mode that simultaneously matches the free spectral range (FSR) of both feedback and lasing rings. In this configuration, the clockwise (CW) lasing mode of the lasing ring couples into the feedback ring via the bottom extraction waveguide. The feedback ring has a slightly different radius of 180 μm, and due to the vernier effect, only modes that match the resonance conditions of both rings are excited in the feedback ring resonator. Utilizing the Rayleigh back-scattering of the feedback ring, part of the light gets coupled from CW into counterclockwise (CCW) and is reflected into the lasing ring resonator. This feedback signal provides seed and locks a dominant mode inside the lasing ring. Using this technique, we observed single-mode lasing with around 15 dB side-mode suppression ratio as shown in FIG. 4F.

The bandwidth of optical gain in Ti:Sa provides opportunities to address a wide range of laser applications. To target a specific wavelength and achieve wavelength-by-design, we use a waveguide distributed Bragg reflector (DBR) grating. The waveguide coupled DBR provides a narrow-band reflection into the microring resonator Ti:Sa laser, locking the lasing mode at the reflection tone (FIG. 4G). Since the FSR of the microring resonator is 124 GHz, a DBR with a 3-dB reflection bandwidth of 90 GHz is selected to guarantee single-mode reflection into the microring Ti:Sa laser cavity. The fabricated DBR grating is 1-mm long where the grating pitch (A) determines the lasing wavelength by: λ_{lasing}=2η_{eff}Λ. Here, Λ=795 nm, n_{eff}=1.81, Λ=219 nm, and the calculated grating strength is κ=20 cm⁻¹. FIG. 4H shows the false color SEM image of the fabricated waveguide DBR, whereas FIG. 4F shows the lasing spectrum at the DBR reflection wavelength with a side-mode suppression ratio of >16 dB. Here, both external ring and external DBR provides a pathway towards single mode operation and wavelength selection. For stable single-mode operation at high power, a more over-coupled microring resonator is required. A more complicated external circuit that combines vernier ring filters and loop mirror, shown in FIG. 1B, could provide a widely tunable single-mode laser emission.

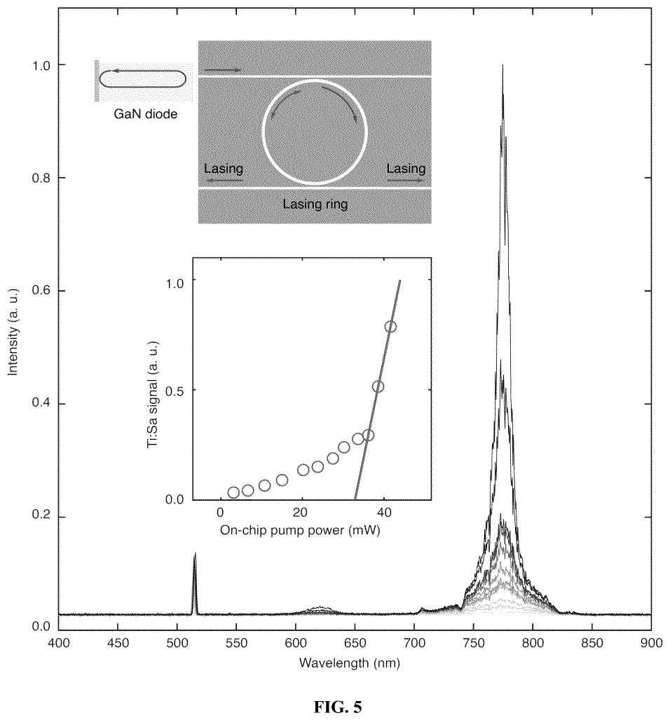

The pump for commercial Ti:Sa lasers usually relies on the table-top frequency-doubled solid-state lasers and optically pumped semiconductor lasers. Since our PIC Ti:Sa laser exhibits a much lower threshold, it can be directly pumped by a commercially available InGaN laser diode. Currently, InGaN diodes cover an emission range in the ultraviolet-to-green band that matches well with the absorption region of the Ti:Sa crystals. Nevertheless, the FP InGaN laser diode exhibits multi-longitudinal modes across its gain bandwidth. If directly pumped into the Ti:Sa chip, only a few modes of the FP laser can be delivered to the microring resonator. Here, we designed the Ti:Sa microring cavity FSR (˜124 GHZ) to match twice that of the laser diode (˜62 GHz). Under this condition, the FP modes of the laser diode are actively pulled into the Ti:Sa microcavity by narrow-band back-reflection as the microring resonance aligns with the FP diode FSR. This results in more than half the optical power being delivered into the Ti:Sa microring cavity achieving diode-based Ti:Sa lasing action. The working principle of the diode-pumped scheme is shown in FIG. 5 top inset. FIG. 5 shows the emission spectrum of the PIC integrated Ti:Sa laser collected through the signal extraction waveguide while being excited by a 520-nm laser diode. Spectral linewidth narrowing indicates that the laser is above threshold when the on-chip power reaches over 30 mW. By integrating the spectrometer data (FIG. 5 bottom inset), a clear lasing threshold behavior appears at an on-chip pump power of 32 mW, as shown by the linear fitting. This proof-of-concept demonstrates a compact single-chip pump laser driving a low power consumption Ti:Sa microlaser, and lays the foundation of future developments into a fully integrated active-passive Ti:Sa PIC. By further engineering an enhanced pump-signal feedback, self-injection locking of the pump laser diode by the Ti:Sa cavity will eventually enable more efficient delivery of the laser diode optical power into the Ti:Sa cavity resulting in an ultra-low threshold turn-key Ti:Sa laser operation.

In conclusion, we have demonstrated the integration of Ti:Sa gain medium onto a PIC. By using a microring resonator, we realized tight mode confinement and simultaneous resonance at the pump and lasing wavelengths, providing a record-low laser threshold to the milliwatt level. By adding external microring and waveguide DBR feedback, we achieved the single-mode lasing at the wavelength by design. With a commercially available FP InGaN laser diode as the pump, turn-key operation of the Ti:Sa laser has been conceptionally demonstrated. A further reduction in the lasing threshold can be achieved by minimizing the waveguide loss, reducing the optical mode size, and using substrate diffused Ti:Sa gain media with a higher Ti³⁺ ion concentration. Improved slope efficiency can be expected by optimizing the lasing cavity geometry and enhancing the optical-ion overlap. Higher lasing power and the integration of a saturable absorber would also allow on-chip femtosecond laser generation. By using more sophisticated photonic circuits with active heater tuning, tunable narrow linewidth lasing is also on the horizon. We anticipate more integrated capabilities in the future by extending the laser wavelength tuning range of the Ti:Sa PIC, providing visible-to-NIR tunable laser light for on-chip atomic clocks and quantum metrology, as well as facilitating the development of consumer markets such as AR/VR equipment and visible light communications. Moreover, when the Ti:Sa is integrated on each chip, the effective cost for a singular laser can be dramatically reduced compared to its free-space commercial counterparts, potentially enabling deployment of Ti:Sa lasers in more spaces other than laboratory settings. Eventually, other waveguide platforms, such as lithium niobate, aluminum nitride, tantala and other solid-state gain media such as Ruby and fluoride crystals, can be integrated into the photonic toolbox to expand the on-chip emission spectrum, thanks to the flexibility of the heterogeneous integration demonstrated in this work.

### Methods

### 1. Device Fabrication.

The process begins with the deposition of SiN thin film on a 4-inch sapphire wafer using low pressure chemical vapor deposition (LPCVD). We define the etching mask using hydrogen silsesquioxane (HSQ) as electron beam resist for the photonic circuits and bonding area. The SiN pattern is then fully etched using a fluorine-based inductively coupled plasma reactive ion etching (ICP-RIE) process. Afterwards, the etching mask is removed by buffered oxide etch (BOE). The Ti:Sa crystal and SiN chip are cleaned with acetone and isopropyl alcohol and the surfaces are activated with piranha and oxygen plasma. Two chips are then flip chip bonded at room temperature. The bonded chip is then coated with plasma enhanced chemical vapor deposition (PECVD) silicon oxynitride, whose index is tuned to match with the sapphire substrate to suppress the radiation loss of the waveguides. The completed chip is cleaved along the sapphire m-plane for side coupling.

### 2. Ti:Sa Laser Characterization and Linewidth Measurement.

On-chip Ti:Sa laser measurements are carried out using a scheme described below. A 532-nm diode-pumped solid-state laser (M2 Equinox) is used for pumping. A neutral-density filter and a half-wave plate control the incident power and polarization. The pump light is then coupled to the chip through a high numerical-aperture free-space lens. At the same time, the lens collects clockwise lasing light and sends it to a free-space photodetector. The chip is mounted on a temperature-controlled stage operated in a range from 25° C. to 50° C., which allows the pump light to be tuned into resonance by thermal tuning. We utilize a 780-nm lensed fiber to collect the output laser signal from the extraction waveguides. A fiber-based wavelength division multiplexer (WDM) separates the residue pump from the lensed fiber output. The lasing signal (>550 nm) is then sent to the optical spectrum analyzer (Thorlabs OSA201C, resolution: 7.5 GHz) and spectrometer (SPM, JAZ, resolution: 0.3 nm). For linewidth measurement, the fiber-coupled Ti:Sa laser signal is sent to beat with a commercial Ti:Sa laser (M2 SolsTis). The laser linewidth is then measured using a fast PD (New focus 1580) connected to an electrical spectrum analyzer (ESA, Agilent N9020A, resolution bandwidth: 43 kHz).

### Example 2

This example describes the preparation of Ti:Sapphire wafers according to the thermal diffusion method disclosed herein. This method provides a more scalable Ti:Sapphire wafer source for monolithic gain integration.

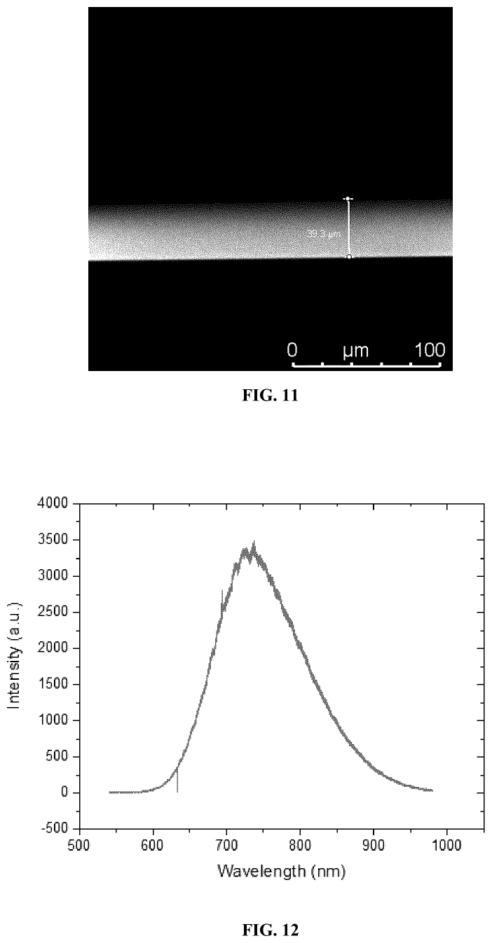

Referring to FIG. 7C, first, 200 nm TiO₂ was deposited onto the sapphire substrate. From steps 2-3, another sapphire wafer was put on top of the above wafer after it was annealed face-to-face. As a result of the face-to-face setup, TiO₂ was prevented from the thermally evaporated material loss at extremely high temperatures, and the titanium ions could be annealed in the correct valence states during vacuum annealing. A two-step annealing process was conducted at 1800° C. and 1900° C. (e.g., the wafers were first heated up to 1800° C. for 2 hours to ensure the TiO₂ decomposes into TI₂O₃ and then heated up to 1900° C. for 2 hours to ensure titanium ions diffuse into the wafers). The same process was also used in a multiple wafer arrangement, as shown in FIGS. 8-10. As shown in FIG. 11, diffusion depth can reach 40 μm using this process. The fluorescence signals in FIG. 12 show strong Ti:Sa emission between 650 and 1000 nm.

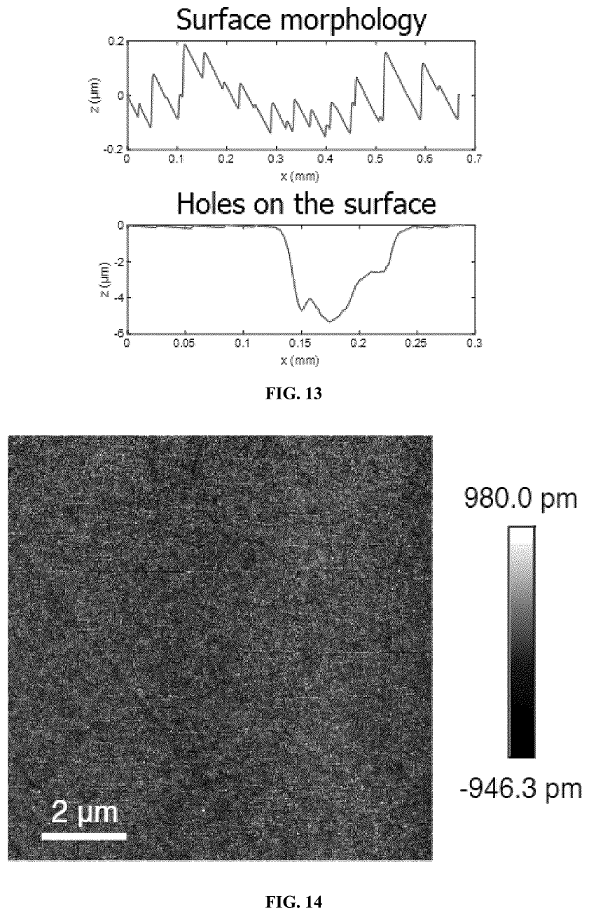

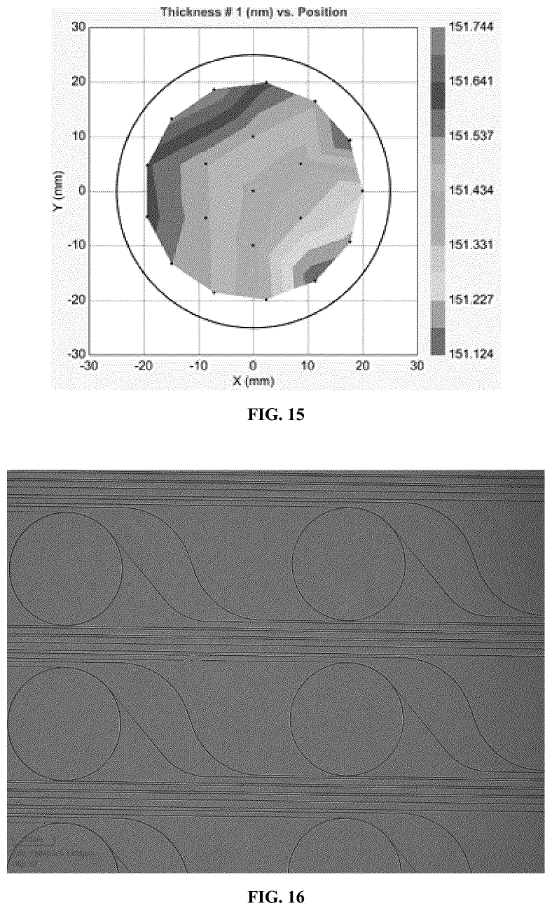

As illustrated in FIG. 13, the diffusion causes the sapphire surface to become very rough. Most of the wafer surface appears to be arranged in staircases, along the miscut angle of sapphire, with deep holes as deep as 10 microns. Accordingly, in step 4 the sapphire wafer was polished (e.g., chemical mechanical polishing) to restore it to epi-ready condition. After polishing the wafer was epi-ready with a roughness of less than 0.2 nanometers (FIG. 14). Next, the SiN thin film, which exhibits very low absorption losses at visible wavelengths, was grown using LPCVD. The LPCVD SiN thickness was very uniform, as illustrated in FIG. 15, which shows a thickness map of the SiN thickness with a thickness variation of less than 0.5% across the entire 2-inch wafer.

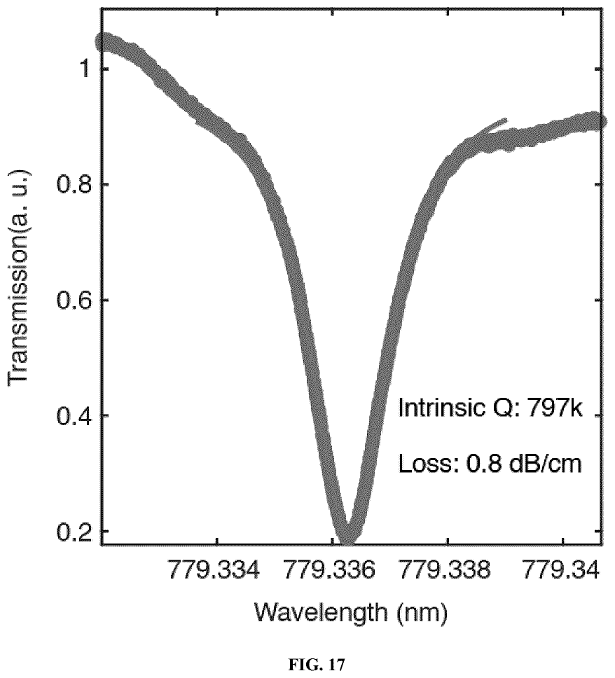

The sixth step involved dicing the deposited wafers into small pieces and patterning the SiN waveguides using Ebeam lithography. In step 7, SiON was deposited using PECVD, which has a matching index to the sapphire substrate to suppress radiation loss. In step 8, the heater was deposited for active laser tuning. The fabricated devices took up less than 0.1 centimeters squared for each device (FIG. 16), while the monolithic photonic circuit integrated Ti:Sa lasers had an intrinsic optical quality factor of over one million (FIG. 17).

### Example 3

This Example shown the fabrication of a photonic circuit integrated mode-locked Ti:Sa laser (FIG. 18). As a first step, stoichiometric silicon nitride was deposited on a sapphire or diffused sapphire substrate using LPCVD. In step 2, the SiN was patterned using electron beam lithography and etched with reactive ion etching. In the third step, gold was deposited on a photonic circuit chip and another Ti:Sa crystal or chip. Fourthly, the photonic circuit chip and the Ti:Sa chip were bonded together with Au—Au bonding. In step 5, the facets were polished to facilitate direct graphene transfer. As a saturable absorber, graphene has a broad absorption spectrum and a short relaxation time constant. Following the evaporation of silicon dioxide or alumina to compensate for waveguide dispersion, the gold mirror was evaporated at the end to form the final FP cavity.

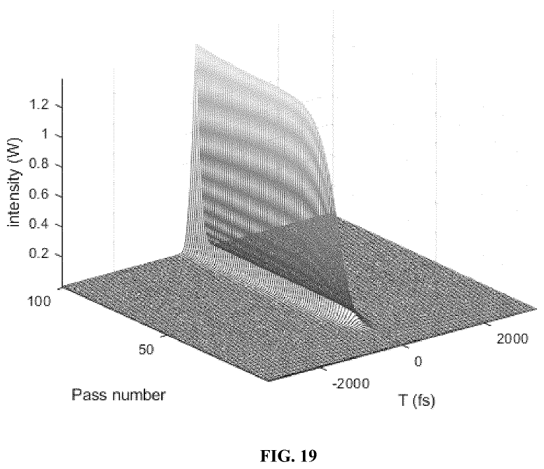

FIG. 19 shows a chart illustrating the temporal evolution of pulse formation in the photonic circuit integrated mode-locked Ti:Sa laser. The signal begins as amplified spontaneous emission noise. With the fast relaxation of the graphene saturation absorber and compensated dispersion, the pulse evolves after 20 round trips, stabilizing after 50 round trips. The theoretical pulse width can be as small as <100 fs.

These Examples show that the integrated approach described herein reduces the size and the cost of the Ti:Sa laser by several orders of magnitude. Without wishing to be bound by theory, it is believed that the integrated Ti:Sa lasers described herein will make a significant contribution to photonics, especially in commercial applications.

### Enumerated Embodiments

### Methods of Preparing a Titanium:Sapphire (Ti:Sa) Wafer

Embodiment 1—A method of preparing a Titanium:Sapphire (Ti:Sa) wafer, the method comprising depositing a titanium layer on a top surface of a first sapphire substrate; positioning a second sapphire substrate on the titanium layer, forming a face-to-face configuration with the titanium layer between the first and second sapphire substrates; annealing the first and second sapphire substrates in the face-to-face configuration, forming an annealed substrate; and polishing the annealed substrate, forming a polished substrate.

Embodiment 2—The method of Embodiment 1, wherein the titanium layer comprises Ti or TiOₓ, wherein x is from 1 to 2.

Embodiment 3—The method of any of Embodiments 1-2, wherein the step of depositing the titanium layer includes depositing titanium to a thickness of at least 50 nm

Embodiment 4—The method of any of Embodiments 1-3, wherein the step of depositing the titanium layer includes depositing titanium to a thickness of 200 nm.

Embodiment 5—The method of any of Embodiments 1-4, wherein the annealing step includes a two-step annealing process comprising: heating the face-to-face configuration at a first temperature, the first temperature decomposing the titanium layer into a decomposed titanium layer; and heating the face-to-face configuration with the decomposed titanium layer at a second temperature, the second temperature diffusing Ti ions into the sapphire substrates; wherein the annealing process is performed under vacuum.

Embodiment 6—The method of any of Embodiments 1-5, wherein the titanium layer comprises TiO₂ and the decomposed titanium layer comprises Ti₂O₃.

Embodiment 7—The method of any of Embodiments 1-6, wherein the first temperature is between about 1750° C. to about 1850° C.

Embodiment 8—The method of any of Embodiments 1-7, wherein the heating at the first temperature is for between about one hour to about three hours.

Embodiment 9—The method of any of Embodiments 1-8, wherein the second temperature is between about 1850° C. to about 1950° C.

Embodiment 10—The method of any of Embodiments 1-9, wherein the heating at the second temperature is for between about one hour to about three hours.

Embodiment 11—The method of any of Embodiments 1-10, wherein the annealed substrate includes a Ti-diffusion depth of between about 1 μm to about 50 μm.

Embodiment 12—The method of any of Embodiments 1-11, wherein the polished substrate includes a roughness of less than 0.2 nm, measured with AFM with Ra.

Embodiment 13—The method of any of Embodiments 1-12, further comprising preparing monolithic photonic circuit integrated Ti:Sapphire laser, the method comprising: growing a thin film on the polished substrate; patterning the thin film, forming a patterned waveguide; depositing an overclad layer over the patterned waveguide; and depositing a heater on the overclad layer.

Embodiment 14—The method of any of Embodiments 1-13, wherein the thin film is selected from the group consisting of silicon nitride (SiN), aluminum nitride (AlN), lithium niobate (LN), tantala, and a combination thereof.

Embodiment 15—The method of any of Embodiments 1-14, wherein the step of growing the SiN thin film includes low-pressure chemical vapor deposition (LPCVD) of the SiN thin film.

Embodiment 16—The method of any of Embodiments 1-15, wherein the step of growing the AlN thin film includes metal organic chemical vapor deposition (MOCVD) of the AlN thin film.

Embodiment 17—The method of any of Embodiments 1-16, wherein the thin film includes a thickness variation of less than 0.5% across the polished substrate.

Embodiment 18—The method of any of Embodiments 1-17, wherein the step of patterning the thin film includes patterning through Ebeam lithography or photolithography.

Embodiment 19—The method of any of Embodiments 1-18, wherein the overclad layer is index matched to a sapphire portion of the patterned waveguide.

Embodiment 20—The method of any of Embodiments 1-19, wherein the overclad layer comprises SiON or an index matching gel.

Embodiment 21—The method of any of Embodiments 1-20, wherein the step of depositing the overclad layer includes plasma-enhanced chemical vapor deposition (PECVD) of the overclad layer on the patterned waveguide.

Embodiment 22—The method of any of Embodiments 1-21, further comprising, prior to the step of patterning the thin film, dicing the polished substrate having the thin film deposited thereon into two or more diced substrates.

Embodiment 23—The method of any of Embodiments 1-22, where the subsequent steps of patterning the thin film, depositing the overclad layer over the patterned waveguide, and depositing the heater on the overclad layer are performed separately for each of the two or more diced substrates.

Embodiment 24—The method of any of Embodiments 1-23, further comprising, prior to the annealing step, positioning at least one additional sapphire substrate over the second substrate with an additional titanium layer formed between each of the additional sapphire substrates, forming a multiple face-to-face configuration.

Embodiment 25—The method of any of Embodiments 1-24, wherein the multiple face-to-face configuration includes nine sapphire substrates and eight titanium layers.

### Methods of Preparing a Titanium:Sapphire (Ti:Sa) Wafer

Embodiment 26—A method of forming a photonic circuit integrated mode-locked Ti:Sa laser, the method comprising: depositing a thin film on a sapphire substrate; patterning and etching the thin film, the patterning and etching forming a photonic circuit chip; depositing gold on the photonic circuit chip; depositing corresponding gold on a Ti:Sa chip; bonding the photonic circuit chip and the Ti:Sa chip together, forming a bonded chip; and forming a Fabry-Pérot (FP) cavity in the bonded chip, the Fabry-Perot cavity being defined by its reflective surfaces at the chip facets.

Embodiment 27—The method of Embodiment 26, wherein the thin film is selected from the group consisting of silicon nitride (SiN), aluminum nitride (AlN), lithium niobate (LN), tantala, and combinations thereof.

Embodiment 28—The method of any of Embodiments 26-27, wherein the bonding step comprises Au—Au bonding or adhesive bonding.

Embodiment 29—The method of any of Embodiments 26-28, wherein the reflective surfaces at the chip facets are formed by evaporated gold mirrors or distributed Bragg reflector mirrors.

Embodiment 30—The method of any of Embodiments 26-29, wherein the sapphire substrate comprises a diffused sapphire substrate.

Embodiment 31—The method of any of Embodiments 26-30, wherein the diffused sapphire substrate comprises the polished substrate according to the method of claim 1.

Embodiment 32—The method of any of Embodiments 26-31, wherein the thin film comprises stoichiometric silicon nitride.

Embodiment 33—The method of any of Embodiments 26-32, wherein the step of depositing the thin film includes low pressure chemical vapor deposition (LPCVD) of the thin film on the sapphire substrate.

Embodiment 34—The method of any of Embodiments 26-33, wherein the patterning of the thin film comprises electron beam lithography.

Embodiment 35—The method of any of Embodiments 26-34, wherein the etching of the thin film comprises reactive ion etching.

Embodiment 36—The method of any of Embodiments 26-35, wherein forming the FP cavity comprises: polishing facets of the bonded chip; transferring graphene; compensating for waveguide dispersion; and evaporating a gold mirror or distributing a Bragg reflector mirror.

Embodiment 37—The method of any of Embodiments 26-36, wherein the step of compensating for waveguide dispersion comprises evaporating at least one of silicon dioxide and alumina.

Embodiment 38—The method of any of Embodiments 26-37, wherein prior to the polishing the bonded chip is diced into multiple bonded chips, and the bonded chips are mounted on a side polishing jig.

Embodiment 39—The method of any of Embodiments 26-38, wherein the transferring of the graphene includes: growing the graphene on copper; coating a front side of the graphene with poly(methyl methacrylate) (PMMA); removing a backside of the graphene using oxygen plasma ashing; dissolving the PMMA coated graphene on copper in ammonium sulfate; transferring the dissolved material to water and then to the chip facet; and removing the PMMA using acetone.

Embodiment 40—The method of any of Embodiments 26-39, wherein the graphene is grown using CVD.

Embodiment 41—The method of any of Embodiments 26-40, wherein the evaporating the gold mirror includes thermal evaporation or ebeam evaporation.

### Photonic Circuit Integrated (PIC) Titanium:Sapphire (Ti:Sa) Laser

Embodiment 42-A photonic circuit integrated (PIC) Titanium:Sapphire (Ti:Sa) laser comprising: a substrate; a waveguide formed on the substrate, the waveguide including a microring portion; a Ti:Sa layer formed over the microring portion of the waveguide, the Ti:Sa layer and the microring portion of the waveguide forming a microring cavity; and a laser source coupled to the waveguide.

Embodiment 43—The PIC-Ti:Sa laser of Embodiment 42, wherein the substrate comprises sapphire or Ti:Sa.

Embodiment 44—The PIC-Ti:Sa laser of any of Embodiments 42-43, wherein the Ti:Sa substrate comprises a Ti:Sa wafer formed according to the method of any of Embodiments 1-25.

Embodiment 45—The PIC-Ti:Sa laser of any of Embodiments 42-44, wherein the waveguide comprises silicon nitride (SiN) or aluminum nitride (AlN).

Embodiment 46—The PIC-Ti:Sa laser of any of Embodiments 42-45, wherein the waveguide comprises a thickness of between 25 nm and 250 nm.

Embodiment 47—The PIC-Ti:Sa laser of any of Embodiments 42-46, wherein the Ti:Sa layer comprises a Ti:Sa wafer formed according to the method of any of Embodiments 1-25.

Embodiment 48—The PIC-Ti:Sa laser of any of Embodiments 42-47, further comprising a dual waveguide coupler.

Embodiment 49—The PIC-Ti:Sa laser of any of Embodiments 42-48, wherein the dual waveguide coupler comprises: a pulley coupler phase-matching a pump mode to a ring resonator mode; and a point coupler extracting a lasing mode without disturbing the pump mode.

Embodiment 50—The PIC-Ti:Sa laser of any of Embodiments 42-49, wherein the laser source comprises a InGaN laser.

Embodiment 51—The PIC-Ti:Sa laser of any of Embodiments 42-50, wherein the optical modes of the pump and gain are less than 1 μm².

Embodiment 52—The PIC-Ti:Sa laser of any of Embodiments 42-51, further comprising a laser threshold of less than 1 mW.

Embodiment 53—The PIC-Ti:Sa laser of any of Embodiments 42-52, further comprising a peak emission wavelength of between 650 nm and 1100 nm.

Embodiment 54—The PIC-Ti:Sa laser of any of Embodiments 42-53, wherein the PIC-Ti:Sa laser is multi-mode.

Embodiment 55—The PIC-Ti:Sa laser of any of Embodiments 42-54, wherein the PIC-Ti:Sa laser is single-mode.

Embodiment 56—The PIC-Ti:Sa laser of any of Embodiments 42-55, further comprising external feedback.

Embodiment 57—The PIC-Ti:Sa laser of any of Embodiments 42-56, wherein the external feedback comprises a feedback ring.

Embodiment 58—The PIC-Ti:Sa laser of any of Embodiments 42-57, wherein the microring portion of the waveguide comprises a clockwise lasing mode and the feedback ring comprises a counterclockwise lasing mode.

Embodiment 59—The PIC-Ti:Sa laser of any of Embodiments 42-58, wherein the external feedback comprises a waveguide distributed Bragg reflector (DBR) grating.

The disclosures of each and every patent, patent application, and publication cited herein are hereby incorporated herein by reference in their entirety.

While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

What is claimed is:

1. A method of preparing a Titanium:Sapphire (Ti:Sa) wafer, the method comprising:
depositing a titanium layer on a top surface of a first sapphire substrate;
positioning a second sapphire substrate on the titanium layer, forming a face-to-face configuration with the titanium layer between the first and second sapphire substrates;
annealing the first and second sapphire substrates in the face-to-face configuration, forming an annealed substrate; and
polishing the annealed substrate, forming a polished substrate.

2. The method of claim 1, wherein the titanium layer comprises Ti or TiOₓ, wherein x is from 1 to 2.

3. The method of claim 1, wherein the step of depositing the titanium layer includes depositing titanium to a thickness of at least 50 nm

4. The method of claim 1, wherein the annealing step includes a two-step annealing process comprising:
heating the face-to-face configuration at a first temperature, the first temperature decomposing the titanium layer into a decomposed titanium layer; and
heating the face-to-face configuration with the decomposed titanium layer at a second temperature, the second temperature diffusing Ti ions into the sapphire substrates;
wherein the annealing process is performed under vacuum.

5. The method of claim 4, wherein the titanium layer comprises TiO₂ and the decomposed titanium layer comprises Ti₂O₃.

6. The method of claim 4, wherein the first temperature is between about 1750° C. to about 1850° C.

7. The method of claim 4, wherein the second temperature is between about 1850° C. to about 1950° C.

8. The method of claim 1, wherein the annealed substrate includes a Ti-diffusion depth of between about 1 μm to about 50 μm.

9. The method of claim 1, wherein the polished substrate includes a roughness of less than 0.2 nm, measured with AFM with Ra.

10. The method of claim 1, further comprising preparing monolithic photonic circuit integrated Ti:Sapphire laser, the method comprising:
growing a thin film on the polished substrate;
patterning the thin film, forming a patterned waveguide;
depositing an overclad layer over the patterned waveguide; and
depositing a heater on the overclad layer.

11. The method of claim 10, wherein the thin film is selected from the group consisting of silicon nitride (SiN), aluminum nitride (AlN), lithium niobate (LN), tantala, and a combination thereof.

12. The method of claim 10, wherein the thin film includes a thickness variation of less than 0.5% across the polished substrate.

13. The method of claim 10, wherein the overclad layer is index matched to a sapphire portion of the patterned waveguide.

14. The method of claim 13, wherein the overclad layer comprises SiON or an index matching gel.

15. The method of claim 10, further comprising, prior to the step of patterning the thin film, dicing the polished substrate having the thin film deposited thereon into two or more diced substrates.

16. The method of claim 15, where the subsequent steps of patterning the thin film, depositing the overclad layer over the patterned waveguide, and depositing the heater on the overclad layer are performed separately for each of the two or more diced substrates.

17. The method of claim 10, further comprising, prior to the annealing step, positioning at least one additional sapphire substrate over the second substrate with an additional titanium layer formed between each of the additional sapphire substrates, forming a multiple face-to-face configuration.

18. A method of forming a photonic circuit integrated mode-locked Ti:Sa laser, the method comprising:
depositing a thin film on a sapphire substrate;
patterning and etching the thin film, the patterning and etching forming a photonic circuit chip;
depositing gold on the photonic circuit chip;
depositing corresponding gold on a Ti:Sa chip;
bonding the photonic circuit chip and the Ti:Sa chip together, forming a bonded chip; and
forming a Fabry-Pérot (FP) cavity in the bonded chip, the Fabry-Perot cavity being defined by its reflective surfaces at the chip facets.

19. The method of claim 18, wherein the thin film is selected from the group consisting of silicon nitride (SiN), aluminum nitride (AlN), lithium niobate (LN), tantala, and combinations thereof.

20. The method of claim 18, wherein the bonding step comprises Au—Au bonding or adhesive bonding.

21. The method of claim 18, wherein the reflective surfaces at the chip facets are formed by evaporated gold mirrors or distributed Bragg reflector mirrors.

22. The method of claim 18, wherein the sapphire substrate comprises a diffused sapphire substrate.

23. The method of claim 22, wherein the diffused sapphire substrate comprises a Titanium:Sapphire (Ti:Sa) wafer prepared according to a method comprising:
depositing a titanium layer on a top surface of a first sapphire substrate;
positioning a second sapphire substrate on the titanium layer, forming a face-to-face configuration with the titanium layer between the first and second sapphire substrates;
annealing the first and second sapphire substrates in the face-to-face configuration, forming an annealed substrate; and
polishing the annealed substrate, forming a polished substrate.

24. The method of claim 18, wherein the thin film comprises stoichiometric silicon nitride.

25. The method of claim 18, wherein forming the FP cavity comprises:
polishing facets of the bonded chip;
transferring graphene;
compensating for waveguide dispersion; and
evaporating a gold mirror or distributing a Bragg reflector mirror.

26. The method of claim 25, wherein the step of compensating for waveguide dispersion comprises evaporating at least one of silicon dioxide and alumina.

27. The method of claim 25, wherein prior to the polishing the bonded chip is diced into multiple bonded chips, and the bonded chips are mounted on a side polishing jig.

28. The method of claim 25, wherein the transferring of the graphene includes:
growing the graphene on copper;
coating a front side of the graphene with poly(methyl methacrylate) (PMMA);
removing a backside of the graphene using oxygen plasma ashing;
dissolving the PMMA coated graphene on copper in ammonium sulfate;
transferring the dissolved material to water and then to the chip facet; and
removing the PMMA using acetone.

29. A photonic circuit integrated (PIC) Titanium:Sapphire (Ti:Sa) laser comprising:
a substrate;
a waveguide formed on the substrate, the waveguide including a microring portion;
a Ti:Sa layer formed over the microring portion of the waveguide, the Ti:Sa layer and the microring portion of the waveguide forming a microring cavity; and
a laser source coupled to the waveguide.

30. The PIC-Ti:Sa laser of claim 29, wherein the substrate comprises sapphire or Ti:Sa.

31. The PIC-Ti:Sa laser of claim 30, wherein the Ti:Sa substrate comprises a Ti:Sa wafer formed according to the method of claim 1.

32. The PIC-Ti:Sa laser of claim 29, wherein the waveguide comprises silicon nitride (SiN) or aluminum nitride (AlN).

33. The PIC-Ti:Sa laser of claim 29, wherein the waveguide comprises a thickness of between 25 nm and 250 nm.

34. The PIC-Ti:Sa laser of claim 29, wherein the Ti:Sa layer comprises a Ti:Sa wafer formed according to a method comprising:
depositing a titanium layer on a top surface of a first sapphire substrate;
positioning a second sapphire substrate on the titanium layer, forming a face-to-face configuration with the titanium layer between the first and second sapphire substrates;
annealing the first and second sapphire substrates in the face-to-face configuration, forming an annealed substrate; and
polishing the annealed substrate, forming a polished substrate.

35. The PIC-Ti:Sa laser of claim 29, further comprising a dual waveguide coupler.

36. The PIC-Ti:Sa laser of claim 35, wherein the dual waveguide coupler comprises:
a pulley coupler phase-matching a pump mode to a ring resonator mode; and
a point coupler extracting a lasing mode without disturbing the pump mode.

37. The PIC-Ti:Sa laser of claim 29, wherein the laser source comprises a InGaN laser.

38. The PIC-Ti:Sa laser of claim 29, wherein the optical modes of the pump and gain are less than 1 μm².

39. The PIC-Ti:Sa laser of claim 29, further comprising a laser threshold of less than 1 mW.

40. The PIC-Ti:Sa laser of claim 29, further comprising a peak emission wavelength of between 650 nm and 1100 nm.

41. The PIC-Ti:Sa laser of claim 29, wherein the PIC-Ti:Sa laser is multi-mode.

42. The PIC-Ti:Sa laser of claim 29, wherein the PIC-Ti:Sa laser is single-mode.

43. The PIC-Ti:Sa laser of claim 42, further comprising external feedback.

44. The PIC-Ti:Sa laser of claim 43, wherein the external feedback comprises a feedback ring.

45. The PIC-Ti:Sa laser of claim 44, wherein the microring portion of the waveguide comprises a clockwise lasing mode and the feedback ring comprises a counterclockwise lasing mode.

46. The PIC-Ti:Sa laser of claim 43, wherein the external feedback comprises a waveguide distributed Bragg reflector (DBR) grating.
